(19) United States
(12) Patent Application Publication
(10) Pub. No.: US 2026/0304946 A1
(43) Pub. Date: Oct. 1, 2026

(54) TUB FORKSHEET AND CFET ARCHITECTURES FOR REDUCED SPACING OF COMPLEMENTARY TRANSISTORS

(71) Applicant: Intel Corporation, Santa Clara, CA (US)

(72) Inventors: Dan Lavric, Portland, OR (US); Glenn Glass, Portland, OR (US); Leonard Guler, Hillsboro, OR (US)

(73) Assignee: Intel Corporation, Santa Clara, CA (US)

(21) Appl. No.: 19/092,834

(22) Filed: Mar. 27, 2025

(51) Int. Cl. H10D 84/85; H10D 30/00; H10D 30/01; H10D 30/47; H10D 62/10; H10D 64/01; H10D 64/68; H10D 84/01

(52) U.S. Cl. CPC H10D 84/852; H10D 30/015; H10D 30/019; H10D 30/47; H10D 30/503; H10D 62/102; H10D 62/121; H10D 64/017; H10D 64/685; H10D 84/0181; H10D 84/0188; H10D 84/856

(57) ABSTRACT

Integrated circuit (IC) devices having forksheet transistors. An IC device may include adjacent forksheet transistors with different gate stacks separated by a dielectric wall. The dielectric wall may be similar to, and centered between, adjacent forksheet spines that are on and between stacks of nanoribbon channels. The gate stacks may include inner gate dielectric layers on nanoribbon channels and outer gate dielectric layers both on the inner gate dielectric layers and on the dielectric wall separating the gate dielectric stacks. Either or both of the inner and outer gate dielectric layers of the adjacent transistors may have different thicknesses or material compositions. The dielectric wall between gate electrodes and gate dielectric stacks may enable independent processing of the transistors gates by dividing the nanoribbon channels into separate gate tubs.

### BACKGROUND

In conventional processing of field-effect transistors (FETs), the gate electrodes and gate insulators of millions of transistors are fabricated concurrently and with matching characteristics (such as gate dielectric thickness). Even limited modifications in gate processing (e.g., for complementary or other transistors with differences between transistor fabrication) may cause surface defects and excessive consumption of channel material. For example, repeated deposition and removal of masking layers may consume and/or damage channel materials or gate dielectrics. Such depositions and removals may be even more difficult or problematic for transistors with limited access to channel materials, such as transistors with reduced spacing between devices or with only one-sided access (e.g., in forksheet FETs).

New techniques, structures, and materials are needed to improve the performance and reliability of integrated circuit (IC) devices, for example, by providing multiple transistor gate variants whose characteristics (such as leakage or switching speed) may be matched to particular applications.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIGS. 1A, 1B, and 1C illustrate cross-sectional profile and plan views of an integrated circuit (IC) device with transistor structures having different gate stacks in adjacent gate electrodes separated by a slim dielectric wall, in accordance with some embodiments;

FIG. 2 illustrates cross-sectional profile views of an IC device with lower nanoribbon stacks under upper nanoribbon stacks in complementary field-effect transistor (CFET) structures between forksheet spines and dielectric walls, in accordance with some embodiments;

FIG. 3 is a flow chart of methods for forming different gate stacks in adjacent transistors, in accordance with some embodiments;

FIGS. 4A, 4B, 4C, 4D, 4E, 4F, 4G, 4H, 4I, 4J, 4K, and 4L illustrate cross-sectional profile views of a workpiece or device with transistor structures having different gate stacks in adjacent gate electrodes separated by a slim dielectric wall, at various stages of manufacture, in accordance with some embodiments;

FIG. 5 illustrates a diagram of an example data server machine employing an IC device having a dielectric wall separating gate electrodes with different gate dielectric stacks; and

FIG. 6 is a block diagram of an example computing device, in accordance with some embodiments.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected,” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicate that two or more elements are in either direct or indirect (with other intervening elements between them) physical or electrical contact with each other, and/or that the two or more elements co-operate or interact with each other (e.g., as in a cause-and-effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Techniques, structures, and materials are disclosed to improve integrated circuit (IC) devices having forksheet metal-oxide-semiconductor (MOS) field-effect transistors (FETs).

Dielectric walls may separate adjacent nanoribbon stacks into individual processing compartments (“tubs”), thereby enabling independent fabrication of adjacent gate dielectric stacks in forksheet FETs. Forksheet FETs may have so-called spines or backbones (e.g., dielectric walls) separating pairs of nanoribbon stacks within the forksheet FETs. During fabrication, dielectric walls may be formed between adjacent forksheet FETs (e.g., centered between two adjacent forksheet spines) to isolate nanoribbon stacks in the adjacent forksheet FETs. Instead of parallel nanoribbon stacks necessarily undergoing the same processing, each nanoribbon stack may have its own gate tub and receive specifically tailored processing. Each gate tub may contain a single nanoribbon stack between a forksheet spine and a dielectric wall between forksheet FETs. The dielectric walls may be formed by etching through dummy gates and by filling the etched openings with dielectric, forming isolations between adjacent forksheet FETs and nanoribbon stacks. Openings may be patterned through a hardmask layer deposited over the walls and nanoribbon stacks, and dummy gate material may be removed through the openings, evacuating selected tubs between the dielectric walls and exposing the nanoribbons in the selected tubs for processing.

The mask openings may be made to evacuate groups of tubs selected for a particular processing operation. For example, the gate tubs for all (or at least many) nanoribbon stacks to have a certain gate characteristic (e.g., to receive a certain gate dielectric material or thickness) may be evacuated together and then receive the further processing concurrently. The hardmask layer may be removed following the completion of the particular processing operation, a new hardmask layer may be deposited, and new openings may be patterned to evacuate a new group of tubs for a next processing operation (e.g., the formation of a second gate dielectric material or thickness). The dielectric walls may be retained after gate formation as electrical isolation between adjacent metal gate electrodes.

The deployment of dielectric walls between adjacent forksheet FETs (and, e.g., the evacuating of gate tubs by selective, isotropic etches) may be in beneficial contrast with conventional alternatives. Typically, a hardmask might cover all nanoribbon stacks before a harsh, isotropic etch removes hardmask material from over selected nanoribbon stacks to be processed. Such an etch may damage (e.g., upper surfaces of) nanoribbons once exposed, and the hardmask removal may be unsatisfactory in multiple ways that undermines subsequent processing of the nanoribbons. For example, edge-placement error might cause a hardmask edge between adjacent nanoribbon stacks to be produced too closely to either the nanoribbon stack to be processed or the nanoribbon stack to remain covered by the hardmask material. Such an error may result in insufficient clearance for processing or insufficient protection for masked nanoribbons. In addition to edge-placement error, the patterned hardmask edge may lack vertical fidelity, for example, having oblique, bowed, or rough sidewalls that result in clearance variations of a few nanometers.

Dielectric walls and the resultant gate-tub processing may be especially advantageous for forksheet FETs and complementary FETs (CFETs). The conventional negative effects of the described hardmask patterning errors may be more severe for forksheet FETs, which have reduced access to channel materials due to the forksheet spine blocking access from one side and which may have wider nanoribbons, both exacerbating wet-etch bias issues removing mask or dummy materials between nanoribbons. Vertical pattern fidelity issues may impact CFETs more severely as well, for example, due to the additional processing required by complementary stacks vertically stacked over one another and due to the higher aspect ratios of the taller double-stacks. Dielectric walls between nanoribbon stacks provide means to overcome these issues in forksheet FETs and complementary FETs and to independently process adjacent nanoribbon stacks.

The tailored processing enabled by the gate tubs may be used to provide multiple gate variants, for example, having different threshold voltages V_{T} and corresponding leakages and switching speeds. An IC device may have multiple gate variants for each of multiple complementary conductivity types. For example, an IC device may have a spread of four or more threshold voltages V_{T} among NMOS FETs and a spread of four or more threshold voltages V_{T} among PMOS FETs. In many embodiments, adjacent transistors have different thicknesses of gate dielectric layers directly on channel nanoribbons. In many embodiments, adjacent transistors have different thicknesses of gate dielectric layers (e.g., high-permittivity or “high-k” layers) over the layers directly on the nanoribbons. For example, gate dielectric layer thicknesses may differ by 2 angstroms (or as much as 5 angstroms) in adjacent transistors. In many embodiments, adjacent transistors have gate dielectric layers with different high-k materials. In some embodiments, adjacent transistors have gate dielectric layers with different material compositions (e.g., elemental ratios) of the same high-k materials.

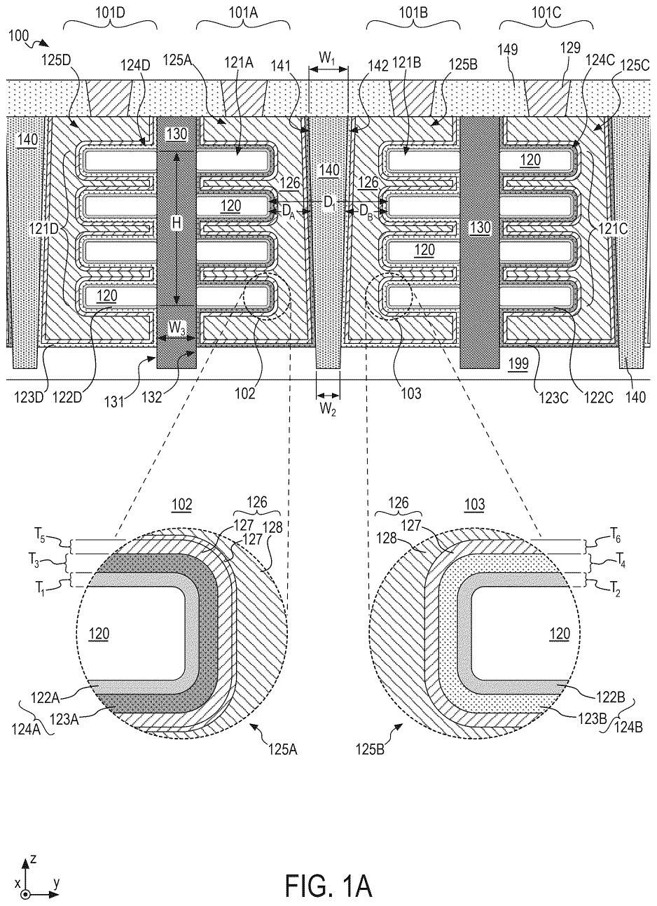

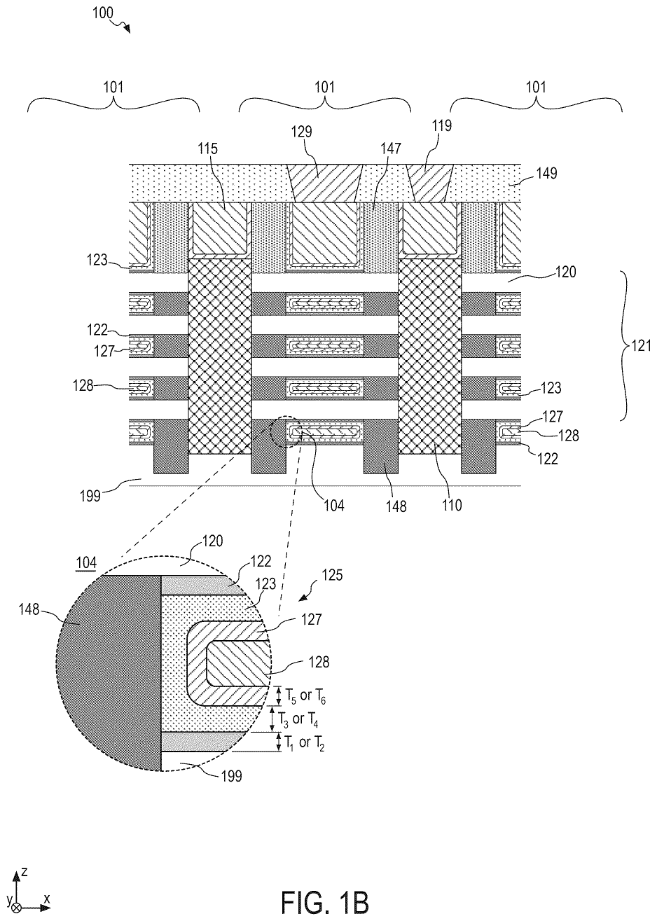

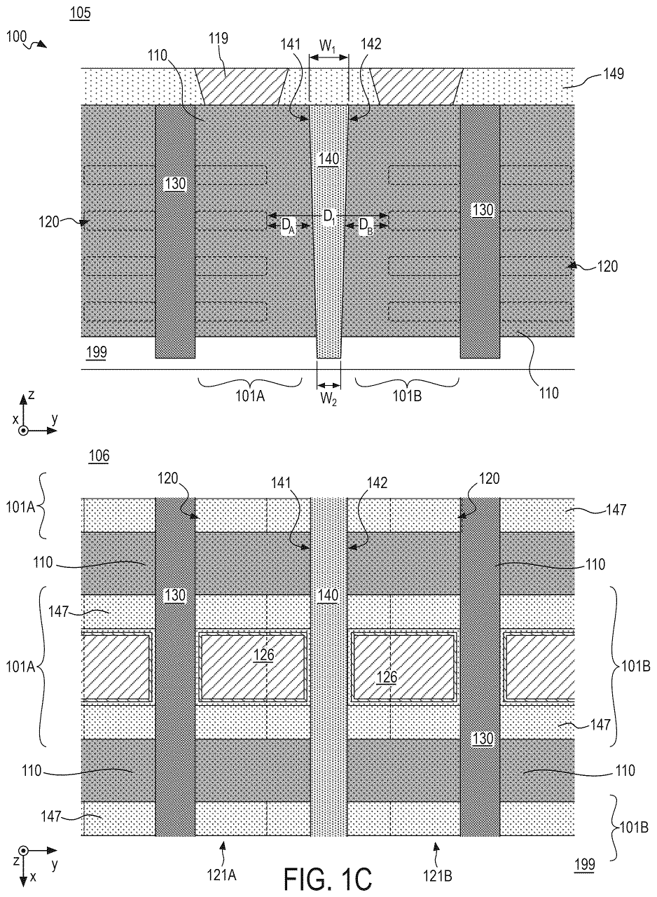

FIGS. 1A, 1B, and 1C illustrate cross-sectional profile and plan views of an IC device 100 with transistor structures 101A, 101B, 101C, 101D having different gate stacks 125A, 125B, 125C, 125D separated by forksheet spines 130 and a slim dielectric wall 140, in accordance with some embodiments. Transistor structures 101A, 101B, 101C, 101D are forksheet FET structures 101 having channel regions in stacks 121A, 121B, 121C, 121D of nanoribbons 120. FIG. 1A shows a y-z viewing plane transversely through nanoribbons 120 in multiple, adjacent stacks 121A, 121B, 121C, 121D and transistor structures 101. FIG. 1A includes multiple (e.g., enlarged) views 102, 103 of exemplary gate stacks 125 (e.g., gate stacks 125A, 125B) on nanoribbons 120. FIG. 1B illustrates an x-z viewing plane longitudinally through nanoribbons 120 in multiple, aligned stacks 121 and transistor structures 101. FIG. 1B includes (e.g., enlarged) views 104 of a gate stack 125 adjacent a nanoribbon 120. FIG. 1C shows a y-z profile view 105 and an x-y plan view 106, both through dielectric walls 140 between and in contact with source or drain bodies 110 in transistor structures 101A, 101B.

FIG. 1A shows device 100 including gate stacks 125A, 125B, 125C, 125D separated by forksheet spines 130 and isolation wall 140 in transistor structures 101A, 101B, 101C, 101D. Isolation walls 140 are dielectric structures on (e.g., in contact with) each of stacks 125A, 125B, 125C, 125D. Spines 130 are also dielectric walls providing isolation and are on (e.g., in contact with) each of stacks 125A, 125B, 125C, 125D. Walls 140, for example, separating gate stacks 125A, 125B and between electrodes 126, extend vertically from above the tops (e.g., upper surfaces) of electrodes 126 to below the bottoms (e.g., lower surfaces) of electrodes 126. Spines 130 are also separating gate stacks 125 (e.g., stacks 125D, 125A and stacks 125B, 125C) and are between electrodes 126, extending vertically from above the tops (e.g., upper surfaces) of electrodes 126 to below the bottoms (e.g., lower surfaces) of electrodes 126. Dielectric walls 140 (along with spines 130) provide isolation (e.g., electrical isolation) between gate electrodes 126 of structures 101A, 101B, 101C, 101D.

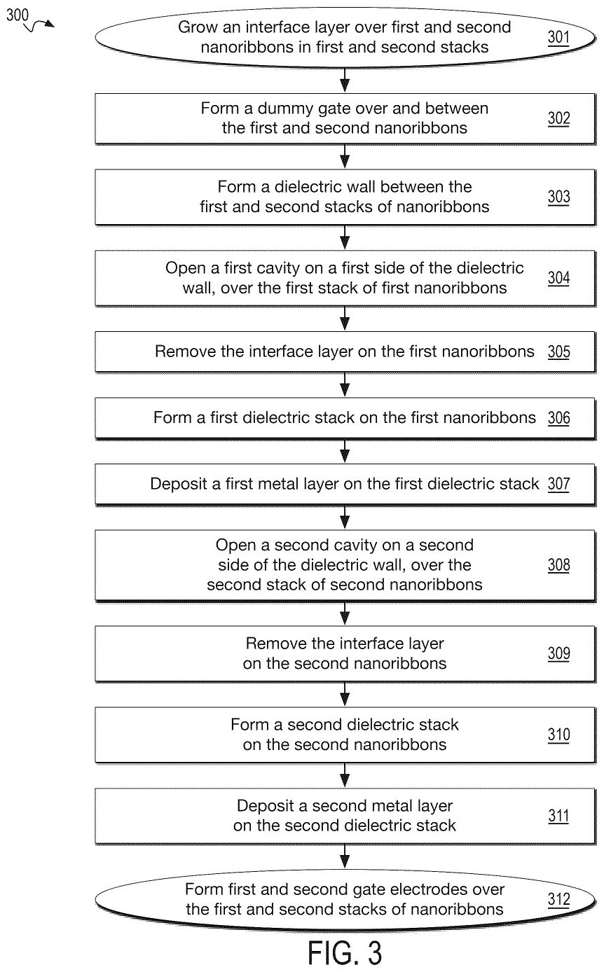

Thin walls 140 enable the tight packing of transistor structures 101A, 101B, 101C, 101D and gate electrodes 126 in device 100. Forksheet spines 130 enable the tight packing of transistor structures 101 and gate electrodes 126, e.g., by providing a minimum distance (e.g., width W₃) between stacks 121 of nanoribbons 120 directly on (e.g., in contact with) spines 130. Dielectric walls 140 and spines 130 also enable the independent processing of gate stacks 125A, 125B, 125C, 125D in structures 101A, 101B, 101C, 101D (e.g., as described elsewhere herein, such as at FIG. 3 and methods 300), which allows for stacks 125 having different insulator layers 122, 123, etc., for example, with different thicknesses, materials, etc. Gate stacks 125 are gate structures that each include a gate electrode 126 and a gate dielectric stack 124 (e.g., a stack 124A, 124B, 124C, or 124D) on electrode 126. Each wall 140 is between a pair of gate electrodes 126, and each electrode 126 is between dielectric wall 140 and spine 130.

Transistor structures 101A, 101B, 101C, 101D may be of the same or of complementary conductivity types (e.g., PMOS and/or NMOS structures 101A, 101B, 101C, 101D). For example, transistor structure 101A may be a p-type structure 101A, and transistor structure 101B may be an n-type structure 101B, or vice versa. In some embodiments, all of transistor structures 101A, 101B, 101C, 101D are of the same conductivity type (e.g., all PMOS structures 101A, 101B, 101C, 101D or all NMOS structures 101A, 101B, 101C, 101D). In many embodiments, transistor structures 101 on a same spine 130 (e.g., structures 101A, 101D and structures 101B, 101C) are of complementary conductivity types. In many embodiments, adjacent structures 101 separated by a wall 140 (e.g., structures 101A, 101B) are of a same conductivity type. For example, in many embodiments, adjacent transistor structures 101A, 101B are of a same conductivity type (e.g., both NMOS structures 101), but have different threshold voltages V_{T} due to (e.g., compositional or thickness) differences in gate stacks 125A, 125B.

Transistor structure 101A includes stack 121A of nanoribbons 120 extending through gate stack 125A. Transistor structure 101B includes stack 121B of nanoribbons 120 extending through gate stack 125B. Transistor structure 101C includes stack 121C of nanoribbons 120 extending through gate stack 125C. Transistor structure 101D includes stack 121D of nanoribbons 120 extending through gate stack 125D. As in the exemplary embodiment of FIG. 1A, some of gate stacks 125A, 125B, 125C, 125D may have different stack compositions. The difference between the compositions of stacks 125A, 125B, 125C, 125D, respectively, may be that stacks 125A, 125B, 125C, 125D include a different quantity of layers (e.g., more or different layers), similar layers but with different materials, etc. For example, first and second compositions of gate stacks 125A, 125B may differ by only (exactly) one of stacks 125A, 125B having a high-k dielectric layer 123 on a transition layer 122.

Some of gate stacks 125 (e.g., dielectric layers 123) are illustrated differently in different transistor structures 101 to highlight potential differences between stacks 125, but any of stacks 125 may be the same or different as other (e.g., adjacent) stacks 125. Magnified views 102, 103 show gate stacks 125A, 125B in greater detail, but each of stacks 125A, 125B, 125C, 125D may have the same or different composition, etc., as any other stack 125. As illustrated in view 102, first gate stack 125A includes a first dielectric stack 124A on first nanoribbons 120, and gate stack 125A includes one or more first metal layers 127 on dielectric stack 124A. View 102 shows an embodiment having multiple layers 127 on stack 124A. First dielectric stack 124A includes dielectric layers 122A on first nanoribbons 120 and insulator layers 123A on dielectric layers 122A. First gate stack 125A may also include a metal (e.g., fill) layer 128 on liner layer 127.

As shown in view 103, second gate stack 125B includes a second dielectric stack 124B on second nanoribbons 120, and gate stack 125B includes one or more second metal layers 127 on dielectric stack 124B. Second dielectric stack 124B includes dielectric layers 122B on second nanoribbons 120 and insulator layers 123B on dielectric layers 122B. Second gate stack 125B may also include a metal (e.g., fill) layer 128 on liner layer 127.

Dielectric layers 122 (e.g., layers 122A, 122B, 122C, 122D) may include any suitable material(s) and may have any suitable thickness(es). Layers 122A, 122B, 122C, 122D are on nanoribbons 120 in transistor structures 101A, 101B, 101C, 101D, respectively, and may provide protection to nanoribbons 120, e.g., during processing. For example, layers 122 may be passivation layers 122, e.g., of a native oxide of a material in nanoribbons 120. In many embodiments, dielectric layers 122 include silicon and oxygen. Layers 122 may be transition layers 122 between nanoribbons 120 and other layers (such as layers 123, etc.) over layers 122. In some embodiments, dielectric layers 122A, 122B, etc., have thicknesses T₁, T₂ less than thicknesses of other layers over layers 122A, 122B. In many embodiments, some dielectric layers 122 (e.g., layer 122A) have a thickness T₁ greater than (or less than) a thickness T₂ of other dielectric layers 122 (e.g., layer 122B). For example, layer 122A may have a thickness T₁ of 1 nm or less and layer 122B may have a thickness T₂ of 1.3 nm or more. In some embodiments, one of layers 122A, 122B, 122C, 122D includes a material not included in the other of layers 122A, 122B, 122C, 122D. Layers 122 may include other suitable materials. Different thicknesses T₁ or T₂ (or different material compositions) of layers 122A, 122B, 122C, 122D may provide different threshold voltages V_{T} for transistor structures 101A, 101B, 101C, 101D. Different thicknesses T₁ or T₂ of layers 122A, 122B, 122C, 122D may provide different thicknesses of nanoribbons 120 in transistor structures 101A, 101B, 101C, 101D.

Insulator layers 123 (e.g., layers 123A, 123B, 123C, 123D) may include any suitable material(s) and may have any suitable thickness(es). Layers 123A, 123B, 123C, 123D are on transition layers 122A, 122B, 122C, 122D in transistor structures 101A, 101B, 101C, 101D, respectively. Layers 123 are on corresponding layers 122 and over each nanoribbon 120. Layers 123 are between each vertically adjacent pair of nanoribbons 120 within a stack 121. Layers 123 are on wall 140 in each stack 125 and on spine 130 between each pair of nanoribbons 120 within a stack 121. In many embodiments, insulator layers 123 have thicknesses T₃, T₄ greater than thicknesses T₁, T₂ of layers 122 on nanoribbons 120. Insulator layers 123 may be high-k dielectric layers 123. For example, layers 123 advantageously include one or more high-k dielectric materials, which may provide design flexibility and/or superior characteristics (such as electrical characteristics) when deployed with, or instead of, other materials.

Layers 123 (e.g., high-k layers 123A, 123B, 123C, 123D) may allow for a greater transconductance gₘ (e.g., for a same voltage on gate electrode 126 and same thickness T₃ or T₄) in transistor structures 101A, 101B, 101C, 101D. High-k layers 123 may allow for greater total thicknesses (e.g., thickness T₁ plus thickness T₃ in stack 125A or thickness T₂ plus thickness T₄ in stack 125B) of dielectric over nanoribbons 120, and so may enable low leakage currents in structures 101 (e.g., for a same voltage on gate electrode 126 while maintain a same transconductance gₘ). High-k layers 123 may enable low leakage currents in structures 101, e.g., with a lower voltage on gate electrode 126 and a same thickness T₃ or T₄. In many embodiments, one or more insulator layers 123 (e.g., layer 123A) have a thickness T₃ greater than (or less than) thickness T₄ of other insulator layers 123 (e.g., layer 123B). For example, layer 123A may have a thickness T₃ of 1.3 nm or less and layer 122B may have a thickness T₄ of 1.8 nm or more. Different thicknesses T₃ or T₄ (or different material compositions) of layers 123A, 123B, 123C, 123D may provide different threshold voltages V_{T} for transistor structures 101A, 101B, 101C, 101D.

Insulator layers 123 may include any suitable material(s). In many embodiments, insulator layers 123 include hafnium and oxygen. In some embodiments, insulator layers 123 include zirconium and oxygen. In some embodiments, insulator layers 123 include hafnium, zirconium, and oxygen. In some embodiments, insulator layers 123A, 123B, 123C, 123D have different material compositions. In some embodiments, for example, insulator layers 123A (or layers 123B, 123C, 123D) include hafnium and zirconium, and insulator layers 123B (or layers 123A, 123C, 123D) include neither, or only one, of hafnium and zirconium (e.g., hafnium but not zirconium, or zirconium but not hafnium). In some embodiments, more than one of layers 123A, 123B, 123C, 123D include hafnium, zirconium, and oxygen (HZO, e.g., in hafnium zirconate or hafnium zirconium oxide), but at different elemental ratios. The material compositions of one or more of layers 123 (e.g., the ratio of hafnium to zirconium) may be varied to increase a relative permittivity of layer(s) 123 (e.g., from about 1:1 to about 2:1 or more). In some embodiments, a dopant (e.g., yttrium) is added to one or more of layers 123 to increase a relative permittivity of layer(s) 123 (e.g., by increasing a proportion of higher-permittivity dielectric phase in layer(s) 123). Any of layers 123 may include one or more of various elements, such as hafnium, zirconium, silicon, oxygen, titanium, tantalum, lanthanum, aluminum, barium, strontium, yttrium, lead, scandium, niobium, and zinc. Layers 123 may include other suitable materials.

Any of gate stacks 125A, 125B, 125C, 125D may include a dipole dopant. In some embodiments, one of gate stacks 125 includes a dipole dopant not present in one or more of the others of gate stacks 125. In some embodiments, gate stacks 125A, 125B, etc., include a same dipole dopant, but the dipole dopant is present at a first height (e.g., of a sum of thicknesses T₁, T₃) from nanoribbons 120 in one or stacks 121 (e.g., stack 121A) greater (or lesser) than a second height (e.g., of a sum of thicknesses T₂, T₄) from nanoribbons 120 in one or more other stacks 121 (e.g., stack 121B). The same dipole dopant may be within different layers 122, 123 (or at a different interface of layers 122, 123) in the different dielectric stacks 124A, 124B.

Gate electrodes 126 (and gate stacks 125A, 125B) may include one or more metal layers 127, 128. Gate electrodes 126, together with dielectric stacks 124A, 124B, 124C, 124D, form gate structures for electrostatically controlling the conduction of transistor structures 101A, 101B, 101C, 101D. Layers 127, 128 may be workfunction metal (WFM) layers 127, 128, e.g., to (e.g., independently) influence threshold voltages V_{T} of transistor structures 101A, 101B, 101C, 101D. Layers 127 may be conformal, liner layers 127 around nanoribbons 120 and dielectric stacks 124, e.g., with a first metal layer 127 on insulator layer 123A around each of nanoribbons 120 in structure 101A, a second metal layer 127 on insulator layer 123B around each of nanoribbons 120 in structure 101B, a third metal layer 127 on insulator layer 123C around each of nanoribbons 120 in structure 101C, and a fourth metal layer 127 on insulator layer 123D around each of nanoribbons 120 in structure 101D.

Transistor structure 101A and gate stack 125A may include one or more metal layers 127 in corresponding electrode 126. Transistor structure 101B and gate stack 125B may include one or more metal layers 127 in corresponding electrode 126. Transistor structure 101C and gate stack 125C may include one or more metal layers 127 in corresponding electrode 126. Transistor structure 101D and gate stack 125D may include one or more metal layers 127 in corresponding electrode 126. Each metal layer 127 is between wall 140 and spine 130 within a stack 125. Each metal layer 127 is between vertically adjacent pairs of nanoribbons 120 within a stack 121, and dielectric layer 123 is between each metal layer 127 and both (e.g., upper and lower) nanoribbons 120 in each pair of nanoribbons 120. A corresponding dielectric layer 123 is between each metal layer 127 and the corresponding dielectric wall 140 and between each metal layer 127 and the corresponding spine 130.

Liner layers 127 in structures 101 (e.g., structures 101A, 101B, etc.) may have different thicknesses T₅, T₆, etc., respectively, for example, with a thickness T₅ (or thickness T₆) greater than a thickness T₆ (or thickness T₅) and having a correspondingly larger impact on the threshold voltage V_{T} of transistor structure 101A (or structure 101B). Layers 127 in structures 101 may have different material compositions. Fill layers 128 in structures 101 may have different material compositions. Layers 127, 128 may include any suitable material(s), including non-metals. In many embodiments, layers 127 include nitrogen (e.g., in a metal nitride) or carbon (e.g., in a metal carbide). In some such embodiments, layers 127 include nitrogen and titanium, molybdenum, or tantalum. In some embodiments, a first layer 127 on a dielectric stack 124 includes titanium and nitrogen, and a second layer 127 on first layer 127 includes nitrogen and tantalum or molybdenum. In some embodiments, layer 127 includes titanium, aluminum, and carbon. In many embodiments, layer 128 includes tungsten.

Walls 140 include opposing first and second sidewalls 141, 142. A width W₁ (or width W₂) of dielectric wall 140 separates sidewalls 141, 142. Width W₁ (or width W₂) separates gate stacks 125A, 125B in transistor structures 101A, 101B (respectively), etc. Dielectric wall 140 (e.g., sidewalls 141, 142) may be nearly vertical. In many embodiments, dielectric wall 140 has widths W₁, W₂ differing only slightly (e.g., in a tapering profile that narrows slightly upwards or downwards. For example, widths W₁, W₂ may be within 1 nm. Width W₁ is defined as the width of wall 140 at a top of wall 140. Width W₂ is defined as the width of wall 140 at a bottom of gate stacks 125, e.g., where wall 140 meets substrate 199 at a bottom of a stack 125 (for example, at layer 123). In some embodiments (e.g., with a planarized backside of transistor structures 101), a horizontal portion of layer 123 may not be present, and wall 140 meets substrate 199 at a vertical portion of layer 123 at a bottom of a stack 125.

Gate stacks 125 on electrodes 126 are separated by dielectric wall 140 and a minimum distance or width W₂ (or width W₁, etc.) between electrodes 126 and stacks 125. In many embodiments, dielectric wall 140 has a minimum width W₂ (or width W₁, etc.) of 12 nm or less between electrodes 126 and stacks 125, which may enable sufficiently tight packing of transistor structures 101 and a consequent conservation of layout area. In some embodiments, dielectric wall 140 has a minimum width W₂ (or width W₁, etc.) of 10 nm or less between electrodes 126 (and stacks 125), which may enable superior packing of transistor structures 101 and conservation of layout area. Such (small widths W₁, W₂ and) tight laying out of structures 101 may be enabled by a fine, high aspect ratio etch (e.g., through and between metal gate electrodes 126). In many embodiments, widths W₁, W₂ of dielectric wall 140 are shorter (e.g., less than) width W₃ of dielectric spine 130. In many embodiments, width W₂ (or width W₁) of wall 140 is approximately equal to a distance D_{A} (or distance D_{B}) between wall 140 and an adjacent stack 121 of nanoribbons 120.

The tight packing of stacks 121 and transistor structures 101 may also be characterized by a small distance D₁ separating adjacent stacks 121 of nanoribbons 120 on different spines 130 (e.g., first and second stacks 121A, 121B of nanoribbons 120). In many embodiments, distance D₁ is less than three times a maximum width W₁ of wall 140 (e.g., with wall 140 centered between stacks 121, a width W₁ from either stack). In many embodiments, distance D₁ is less than 36 nm.

Isolation walls 140 include any suitable material(s), for example, a dielectric material. Wall 140 advantageously includes a low-k (low-permittivity) dielectric material. Wall 140 advantageously has an etch selectivity with other adjacent structures. In many embodiments, wall 140 includes silicon and nitrogen (e.g., in a nitride of silicon). In some embodiments, wall 140 includes silicon and oxygen (e.g., in an oxide of silicon). In some embodiments, wall 140 includes carbon and/or nitrogen, for example, in addition to silicon and oxygen. In many embodiments, walls 140 have a composition similar to or the same as dielectric spines 130.

Isolation walls 140 (in conjunction with spines 130) may enable the independent processing of gate stacks 125A, 125B, 125C, 125D in structures 101A, 101B, 101C, 101D (e.g., as described at least at FIG. 3 and methods 300), which allows for stacks 125 of various compositions (e.g., having layers 122, 123, 127, etc., of different thicknesses T₁, T₂, T₃, T₄, T₅, T₆, and/or including different materials).

Much of the stacks 125 of layers around nanoribbons 120 are also on or adjacent sidewalls 141, 142 of isolation walls 140 and sidewalls 131, 132 of dielectric spines 130. Insulator layer 123A is on sidewall 141 of a wall 140 and sidewall 132 of a spine 130. Insulator layer 123B is on sidewall 142 of a wall 140 and sidewall 131 of a spine 130. Insulator layer 123C is on sidewall 141 of a wall 140 and sidewall 132 of a spine 130. Insulator layer 123D is on sidewall 142 of a wall 140 and sidewall 131 of a spine 130. In transistor structures 101A, 101C, metal layers 127 are on insulator layers 123A, 123C on sidewalls 141, 132 of wall 140 and spine 130, respectively. In transistor structures 101B, 101D, metal layers 127 are on insulator layers 123B, 123D on sidewalls 142, 131 of wall 140 and spine 130, respectively. Notably, gate dielectric layers 122 on nanoribbons 120 may be absent from sidewalls 141, 142 of isolation wall 140 and sidewalls 131, 132 of dielectric spines 130, as in the exemplary embodiment of FIG. 1A.

Nanoribbons 120 in stack 121A, etc., may be the same or different than nanoribbons 120 in stacks 121B, 121C, 121D, etc. For example, nanoribbons 120 in the different stacks 121 may be of the same or different materials, have the same or different thicknesses, etc. Nanoribbons 120 may have any suitable width (and may be, e.g., nanowire nanoribbons 120 or nanosheet nanoribbons 120). Nanoribbons 120 may be of any suitable (e.g., semiconducting) material(s). In many embodiments, nanoribbons 120 include silicon. In some embodiments, at least some of nanoribbons 120 include germanium.

Dielectric spines 130 include any suitable material(s), for example, a dielectric material. Spine 130 advantageously includes a low-k dielectric material. Spine 130 advantageously has an etch selectivity with other adjacent structures. In many embodiments, spine 130 includes silicon and nitrogen (e.g., in a nitride of silicon). In some embodiments, spine 130 includes silicon and oxygen (e.g., in an oxide of silicon). In some embodiments, spine 130 includes carbon and/or nitrogen, for example, in addition to silicon and oxygen. In many embodiments, spines 130 have a composition similar to or the same as dielectric walls 140.

Gate vias 129 are metallization structures that couple (e.g., electrically couple) gate electrodes 126, for example, with an interconnect network (not shown) above transistor structures 101. Vias 129 may include any suitable material(s), including non-metals. Vias 129 may include multiple layers of metals, for example, a liner (e.g., barrier or seed) layer around a fill layer. Gate vias 129 are through a dielectric layer 149 over transistor structures 101. Dielectric layer 149 may be of any suitable material, such as a low-k dielectric material.

Substrate 199 may include any suitable material or materials. Substrate 199 may be an IC substrate, such as an IC die or wafer. In some examples, the substrate may include monocrystalline silicon (including silicon on insulator (SOI)), polycrystalline silicon, germanium, silicon germanium, a III-V alloy material (e.g., gallium arsenide), a silicon carbide (e.g., SiC), a sapphire (e.g., Al₂O₃), or any combination thereof. Substrate 199 may also include semiconductor materials, metals, dielectrics, dopants, and other materials commonly found in semiconductor substrates. Substrate 199 may refer specifically to a base material (for example, a thick base or layer of semiconductor material) that other materials (such as metals and dielectrics) are built up on. In some contexts, substrate 199 may refer to a base material layer and any build-up layers, etc., over the base. Transistor structures 101 may be over a dielectric layer over other (e.g., semiconductor) materials.

FIG. 1B illustrates one or more gate stacks 125 on and between nanoribbons 120 in multiple, aligned stacks 121 and transistor structures 101 in device 100. Stacks 121 of nanoribbons 120 extend between, and couple, source or drain bodies 110. Any of transistor structures 101 in FIG. 1B may be any of structures 101A, 101B, 101C, 101D, as described at FIG. 1A. For example, gate stack 125 in FIG. 1B may be either of stacks 125A, 125B, 125C, 125D, as described at FIG. 1A. Dielectric walls 140 and spines 130 (not shown in FIG. 1B) are between and in contact with source and drain bodies 110 in transistor structures 101. Magnified view 104 shows a gate stack 125 in greater detail. Gate stack 125 includes dielectric layer 122 on nanoribbon 120 and insulator layer 123 on dielectric layer 122. Gate stack 125 includes metal (e.g., fill) layer 128 on liner layer 127 (on layer 123).

Source or drain bodies 110 are electrically and physically coupled to ends of nanoribbons 120 (e.g., channel regions). Source or drain bodies 110 may be impurity doped regions, e.g., regions of semiconductor material doped with one or more electrically active impurities and having increased charge-carrier availabilities and associated conductivities. Bodies 110 in different transistor structures 101 may be doped with an opposite type (e.g., n-or p-type) or of similar type. Source or drain bodies 110 may include a predominant semiconductor material, and one or more n-dopants (such as phosphorus, arsenic, or antimony) or p-type impurities (such as boron or aluminum). Other dopant materials may be used. Any suitable means of formation may be used. Bodies 110 may be epitaxially grown semiconductor regions, for example, of a Group IV semiconductor material (e.g., Si, Ge, SiGe, GeSn alloy). Other semiconductor materials may be employed. Bodies 110 may be substantially crystalline. Source or drain bodies 110 may be polycrystalline or substantially monocrystalline, e.g., having long-range order at least adjacent ends of nanoribbons 120 (e.g., to both sides of bodies 110) and merging or joining into a unitary body with few grain boundaries.

Source or drain bodies 110 are electrically and physically coupled to opposite ends of nanoribbons 120 (e.g., channel regions). In many embodiments, transistor structures 101 are each physically symmetrical about nanoribbons 120 (e.g., channel regions) and gate electrodes 126, and identifiers “drain” and “source” for bodies 110 may be reversed interchangeably in many contexts. However, the classification of source or drain bodies 110 may be by the electrical relationships of transistor structures 101 and bodies 110 to other components in a given circuit (e.g., and the consequent direction of current flow through structures 101 and bodies 110). Some source or drain bodies 110 may simultaneously be a source body 110 in one transistor structure 101 and a drain body 110 in another transistor structure 101.

Source and drain contact structures 115 are metallization structures 115 that couple (e.g., electrically couple) bodies 110, for example, with an interconnect network (not shown) above transistor structures 101. Contact structures 115 may include any suitable material(s), including non-metals. For example, contact structures 115 may include an interface (e.g., silicide) layer on bodies 110. Structures 115 may include multiple layers of metals, for example, a liner (e.g., barrier or seed) layer around a fill layer.

Contact vias 119 are metallization structures that couple (e.g., electrically couple) contact structures 115, for example, with an interconnect network (not shown) above transistor structures 101. Vias 119 may include any suitable material(s), including non-metals. Vias 119 may include multiple layers of metals, for example, a liner (e.g., barrier or seed) layer around a fill layer.

Spacers 147, 148 are isolation structures, e.g., of insulator material (such as a low-k dielectric), adjacent gate electrodes 126. Spacers 148 provide isolation between electrodes 126 and bodies 110. Spacers 147 provide isolation between electrodes 126 and bodies 110 and contact structures 115 over bodies 110.

FIG. 1C shows dielectric wall 140 and spines 130 between and in contact with source and drain bodies 110 in both of transistor structures 101A, 101B, etc. View 105 illustrates a cross-sectional, y-z profile view through dielectric walls 140 and source or drain bodies 110 in transistor structures 101A, 101B. View 106 shows a cross-sectional, x-y plan view through dielectric walls 140, spines 130, source or drain bodies 110, and gate electrodes 126 in transistor structures 101A, 101B, etc. Each wall 140 is between a pair of source or drain bodies 110, and each body 110 is between a dielectric wall 140 and spine 130. Each wall 140 and spine 130 has sidewalls 141, 142, 131, 132 on different source or drain bodies 110, and each body 110 is (on and) between dielectric sidewalls 141, 142, 131, 132 of different dielectric walls 140 and spines 130.

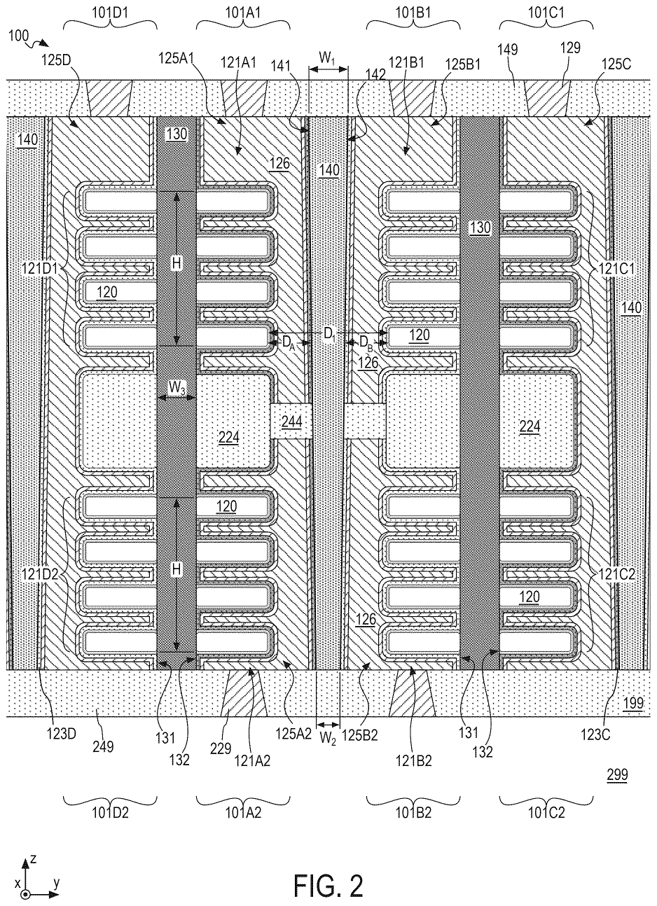

FIG. 2 illustrates cross-sectional profile views of IC device 100 with lower nanoribbon stacks 121A2, 121B2, 121C2, 121D2 under upper nanoribbon stacks 121A1, 121B1, 121C1, 121D1 in CFET structures 101 between forksheet spines 130 and dielectric walls 140, in accordance with some embodiments. Tall, double stacks 121 of nanoribbons 120 having different gate stacks 125 may be enabled by dielectric walls 140 and spine 130.

Device 100 includes transistor structures 101A1, 101B1, 101C1, 101D1 of a first conductivity type over (e.g., vertically aligned with) transistor structures 101A2, 101B2, 101C2, 101D2 of a second conductivity type. Each of stacks 121A2, 121B2, 121C2, 121D2 is on the same spine 130 and between the same spine 130 and wall 140 as corresponding stack 121A1, 121B1, 121C1, 121D1. In some embodiments, lower, complementary structures 101 (e.g., structures 101D2, 101C2) share gate stacks 125 (e.g., stacks 125D, 125C) with upper structures 101 (e.g., structures 101D1, 101C1, respectively). In other embodiments, lower, complementary structures 101 (e.g., structures 101A2, 101B2) have gate stacks 125 (e.g., stacks 125A2, 125B2) distinct from stacks 125 (e.g., stacks 125A1, 125B1) of upper structures 101 (e.g., structures 101A1, 101B1, respectively). For example, an insulator layer 244 is between (and electrically isolates) gate stacks 125A1, 125B1 from stacks 125A2, 125B2, respectively.

Corresponding upper and lower gate stacks 125 may have the same or different compositions (for example, thicknesses and/or material compositions of layers 122, 123, 127). Dielectric isolations 224 may enable separate processing of upper and lower stacks 121, e.g., different gate dielectric layers 123 on nanoribbons 120 in upper and lower stacks 121. Isolations 224 may provide necessary vertical separation for independent processing of gate stacks 125 above and below isolations 224.

Backside vias 229 are through backside dielectric layer 249 and may be much as gate vias 129, for example, metallization structures that couple (e.g., electrically couple) gate electrodes 126, for example, with an interconnect network (not shown), but below transistor structures 101. Vias 229 may include any suitable material(s), including non-metals. Vias 229 may include multiple layers of metals, for example, a liner (e.g., barrier or seed) layer around a fill layer. Gate vias 229 are through a dielectric layer 249 under transistor structures 101. Dielectric layer 249 may be much as layer 149, e.g., of any suitable material, such as a low-k dielectric material.

IC device 100 may include or be coupled to a substrate or other host component 299. Host component 299 may be a package substrate, an interposer, an IC die, etc. For example, substrate 199 may be an IC die that includes transistor structures 101, substrate 199 may be coupled (e.g., soldered or otherwise bonded) to host component 299, and device 100 and transistor structures 101 may be coupled to a power supply (not shown) through host component 299.

Host component 299 is a planar platform and may include dielectric and metallization structures. Host component 299 mechanically supports and electrically couples one or more IC devices 100. At least one side of host component 299 includes substrate interconnect interfaces for bonding to one or more IC devices 100. IC device 100 may be direct bonded, e.g., hybrid bonded, to host component 299 or otherwise bonded, e.g., by optional solder bumps. The opposite side of host component 299 may include similar interfaces, e.g., copper pads for socketing and/or solder bumps for bonding device 100 to a host component, such as a printed circuit board (PCB). Host component 299 may be any host component with substrate interconnect interfaces, such as a package host component 299 or interposer, etc. Host component 299 may itself be a die. In many embodiments, host component 299 includes organic dielectric(s), such as a resin or other polymer, between metallization layers.

FIG. 3 is a flow chart of methods 300 for forming different gate stacks in adjacent transistors, in accordance with some embodiments. Methods 300 include operations 301-312. Some operations shown in FIG. 3 are optional. Additional operations may be included. FIG. 3 shows an example sequence, but the operations can be done in other orders as well, and some operations may be omitted. Some operations can also be performed multiple times before other operations are performed. For example, multiple layers of a same type may be grown or deposited before the next type of layer is grown or deposited. Some operations may be included within other operations so that the number of operations illustrated in FIG. 3 is not a limitation of the methods 300.

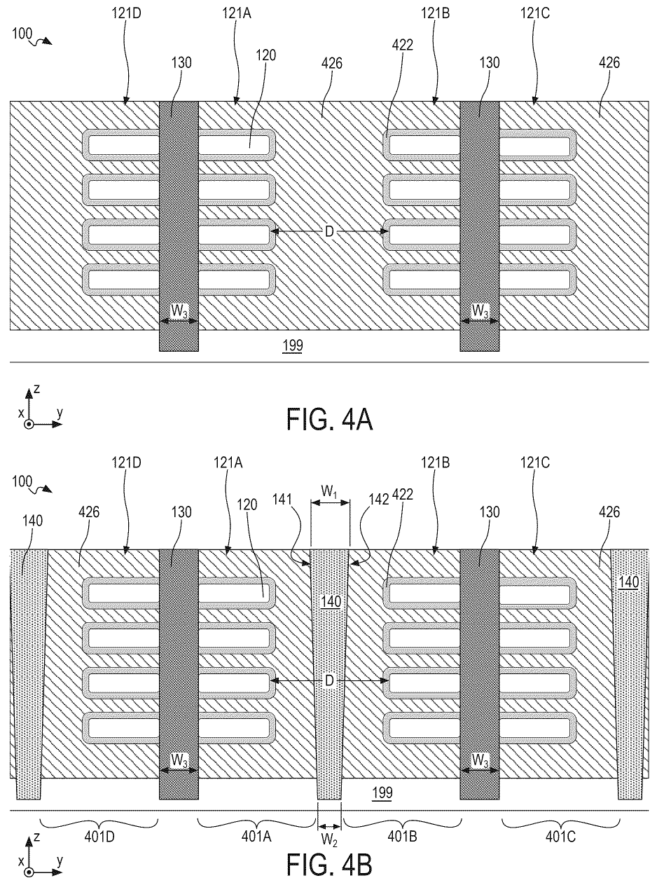

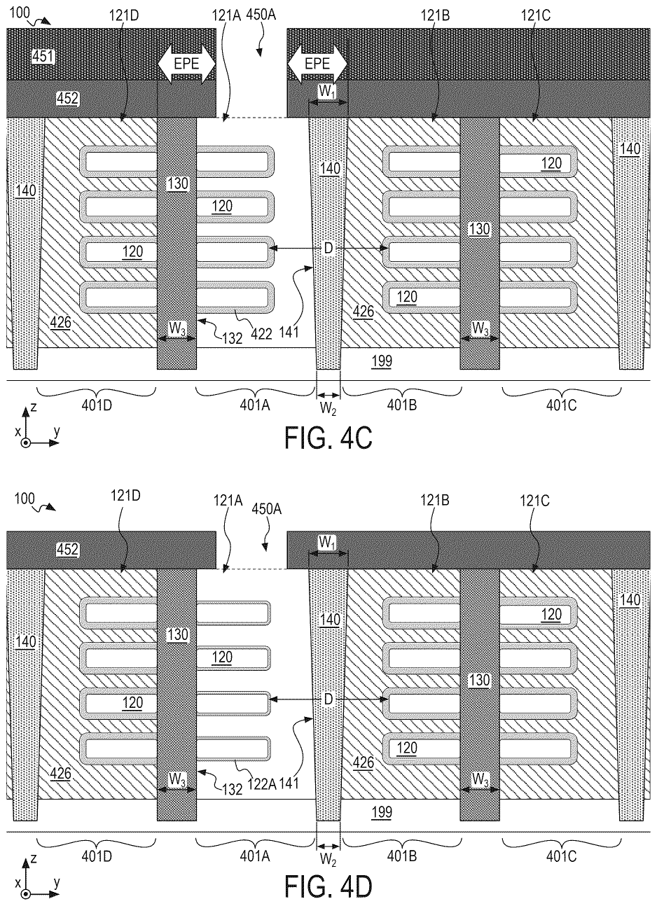

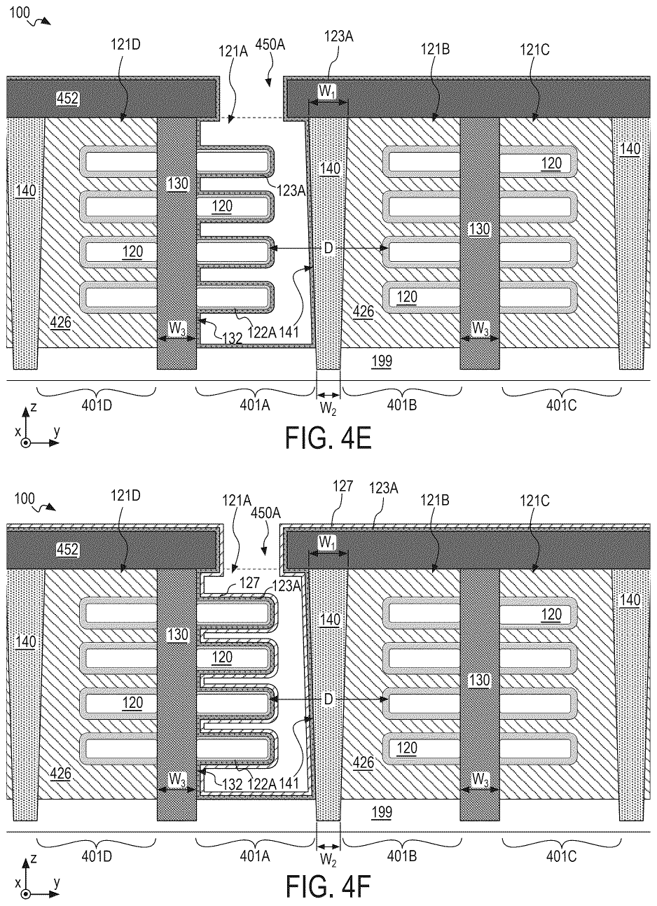

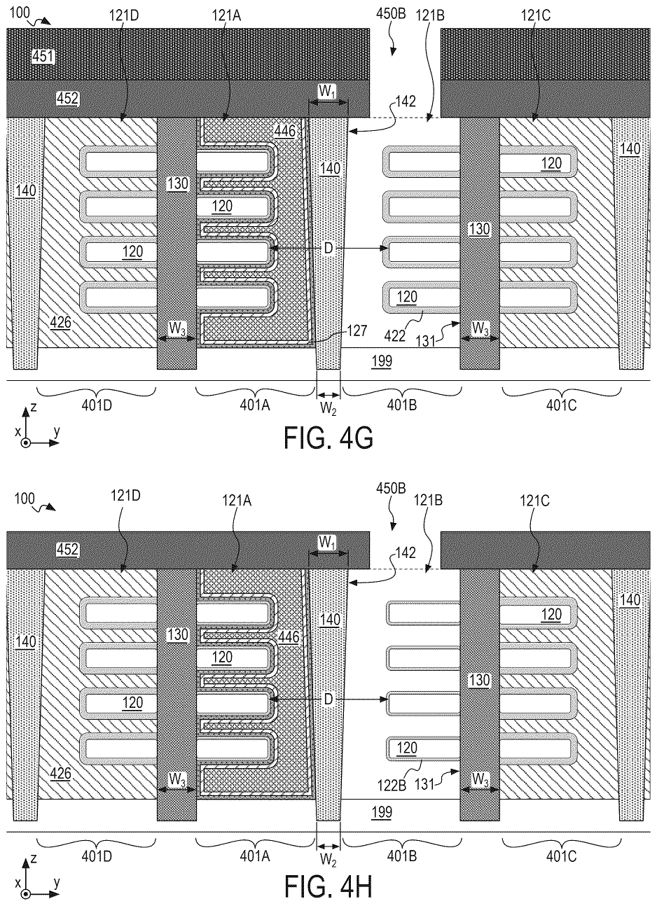

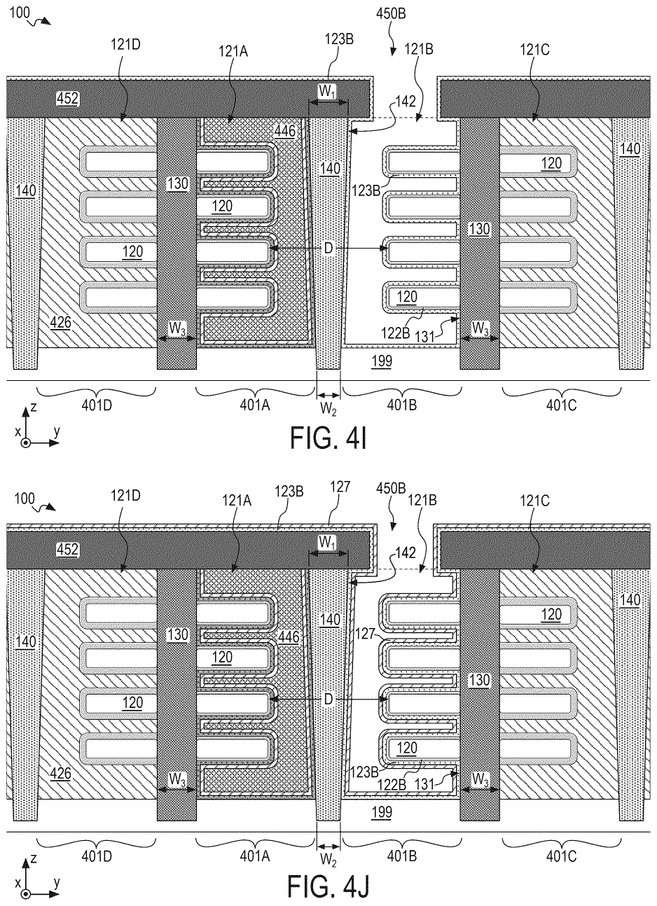

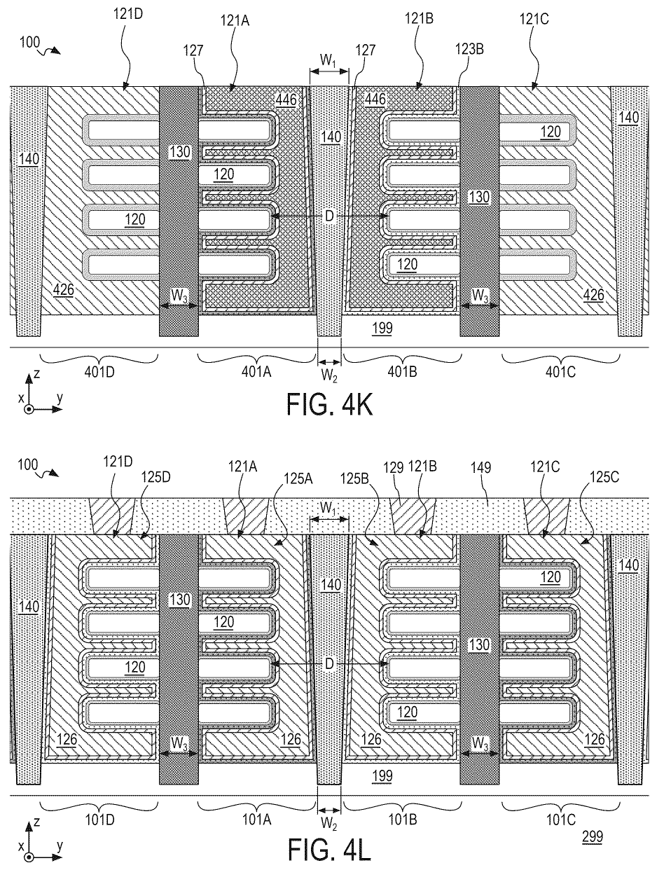

FIGS. 4A, 4B, 4C, 4D, 4E, 4F, 4G, 4H, 4I, 4J, 4K, and 4L illustrate cross-sectional profile views of a workpiece or device 100 with transistor structures 101A, 101B, etc., having different gate stacks 125A, 125B, etc., in adjacent gate electrodes 126 separated by a slim dielectric wall 140, at various stages of manufacture, in accordance with some embodiments. FIGS. 4A-4L show possible examples of intermediate structures during an embodiment of a practice of methods 300 of FIG. 3. Although most of FIGS. 4A-4L illustrate the fabrication of transistor structures 101A, 101B (using, for example, gate tubs 401A, 401B), other transistor structures 101 may be similarly fabricated (for example, in other gate tubs 401 between dielectric spines 130 and walls 140).

Returning to FIG. 3, methods 300 begin at optional operation 301 with growing an interface layer over nanoribbons in adjacent (e.g., first and second) nanoribbon stacks. The interface layer may be between the nanoribbons and a subsequently deposited dummy gate. The interface layer may be a protective layer, e.g., that shields the nanoribbons from subsequent processing. For example, the interface layer may be a passivation layer (e.g., of a native oxide) that protects the nanoribbons from a subsequent deposition (and removal etch) of a dummy gate. Each nanoribbon may be covered by a thin interface (e.g., passivation) layer separate from the other nanoribbons and interface layers. In many embodiments, the interface layer includes oxygen. In many embodiments, the interface layer is on nanoribbons that include silicon, and the interface layer includes oxygen and silicon (e.g., in an oxide of silicon). The interface layer may be grown by any suitable means. In some embodiments, the interface layer is grown by exposure to oxygen, e.g., with an ozone treatment.

The nanoribbon stacks may be received on or in a substrate, such as an IC die or wafer, e.g., much as described of substrate 199 at FIG. 1A. The nanoribbons and nanoribbon stacks may be much as described of nanoribbons 120 and stacks 121 (e.g., stacks 121A, 121B, 121C, 121D) at FIG. 1A. For example, pairs of adjacent nanoribbon stacks may be on and separated by a dielectric spine, and adjacent (e.g., first and second) nanoribbon stacks may be between a pair of adjacent dielectric spines. In some embodiments, adjacent first and second nanoribbon stacks (e.g., between a pair of adjacent dielectric spines) are over adjacent third and fourth nanoribbon stacks (e.g., between the same pair of adjacent dielectric spines), for example, much like an adjacent pair of stacks 121A1, 121B1, 121C1, 121D1 over a corresponding pair of stacks 121A2, 121B2, 121C2, 121D2) at FIG. 2. The third nanoribbon stack may be under the first nanoribbon stack and on the same dielectric spine (and on the same side of the dielectric spine) as the first nanoribbon stack. The fourth nanoribbon stack may be under the second nanoribbon stack and on the same dielectric spine (and on the same side of the dielectric spine) as the second nanoribbon stack. In some embodiments, the upper (first and second) stacks of nanoribbons are coupled between respective semiconductor (source and drain) bodies of a first conductivity type (e.g., n-or p-type), and the third and fourth stacks of nanoribbons are coupled between respective semiconductor (source and drain) bodies of a second conductivity type (e.g., p-or n-type).

In some embodiments, the nanoribbon stacks are formed, for example, by anisotropic etches bisecting stacks of wide nanoribbons. Dielectric spines may then be deposited in the bisector openings, on and between the nanoribbon remainders. The nanoribbons may be released from intervening sacrificial layers after source and drain bodies are grown on ends of the nanoribbons.

Returning to FIG. 3, methods 300 continue at operation 302 with forming a dummy gate over the nanoribbon stacks. The dummy gate may be grown by any suitable means. In many embodiments, the dummy gate is formed by depositing a metal over and between nanoribbons in the first stack and between nanoribbons in the second stack. In some such embodiments, the metal is deposited on the protective layers on the nanoribbons. In some embodiments, the deposited metal is tungsten. The dummy gate may be of any suitable material(s), for example, a material that may be etched through by a high-aspect ratio etch.

FIG. 4A shows interface layers 422 on nanoribbons 120 and dummy gate 426 on layers 422 and over nanoribbons 120 in workpiece or IC device 100, in accordance with some embodiments, for example, following a performance of growing and forming operations 301 and 302. Nanoribbons 120 in adjacent stacks 121A, 121B on different spines 130 are separated by a distance D₁. Nanoribbons 120 in adjacent stacks 121D, 121A and stacks 121B, 121C are on same spines 130 and are separated by width W₃. In the exemplary embodiment of FIG. 4A, nanoribbons 120 and substrate 199 include silicon, interface layers 422 include silicon and oxygen, and dummy gate 426 includes tungsten.

Returning to FIG. 3, methods 300 continue by forming a dielectric wall between the first and second stacks of nanoribbons at operation 303. The dielectric wall may be formed by any suitable means. In many embodiments, the dielectric wall is formed between first and second portions of a dummy gate. For example, the dielectric wall may be formed by etching between first and second portions of the dummy gate and by depositing a dielectric material in the opening etched between the first and second portions. The etch may be a dry, anisotropic etch or any other suitable etch. The dielectric wall may have opposing first and second sidewalls with the first portion of the dummy gate on the first sidewall and the second portion of the dummy gate on the second sidewall. Multiple dielectric walls may be formed, e.g., centered between dielectric spines and between paired nanoribbon stacks with each stack of nanoribbons between a dielectric wall and a dielectric spine.

In many embodiments, forming the dielectric wall forms separate first and second tubs with the first stack of nanoribbons in the first tub and the second stack of nanoribbons in the second tub, for example, with each tub between a dielectric wall and a dielectric spine. In many embodiments, both the first and second tubs include no third stack of nanoribbons, e.g., the first stack of nanoribbons (and no other nanoribbon stack) is in the first tub and the second stack of nanoribbons (and no other nanoribbon stack) is in the second tub.

In some embodiments, forming the dielectric wall between the first and second stacks of nanoribbons forms the dielectric wall between third and fourth stacks of nanoribbons (e.g., with the third stack of nanoribbons under the first stack of nanoribbons and on the same dielectric spine, and with the fourth stack of nanoribbons under the second stack of nanoribbons and on the same (second) dielectric spine). In some such embodiments, the upper (first and second) stacks of nanoribbons are coupled between semiconductor (source and drain) bodies of a first conductivity type (e.g., n-or p-type), and the third and fourth stacks of nanoribbons are coupled between semiconductor (source and drain) bodies of a second conductivity type (e.g., p-or n-type).

The dielectric wall may include any suitable material(s), such as a low-k dielectric material. The dielectric wall may be much as described of dielectric wall 140 at FIG. 1A. In many embodiments, the dielectric wall includes silicon and nitrogen.

FIG. 4B illustrates isolation walls 140 through dummy gate 426 and between adjacent nanoribbon stacks 121A, 121B and gate tubs 401A, 401B in workpiece or device 100, in accordance with some embodiments, for example, following a performance of forming operation 303. In the exemplary embodiment of FIG. 4B, portions of dummy gate 426 are still in gate tubs 401. Other gate tubs 401D, 401C are to either side (e.g., in the y-directions) of tubs 401A, 401B and dielectric spines 130, between spines 130 and other walls 140.

Returning to FIG. 3, methods 300 continue with opening a first cavity on a first side of the dielectric wall at operation 304. The first cavity may be a gate tub for processing the first stack of nanoribbons. The first cavity may be opened by any suitable means. In many embodiments, the first cavity is opened by removing the first portion of the dummy gate from the first sidewall and from over the first stack of nanoribbons. In many embodiments, the dummy gate material is removed by a selective isotropic etch. In some embodiments, the dummy gate material is removed by a wet etch. In some embodiments, a mask layer is deposited over the substrate (including the dummy gate and dielectric walls), a mask opening is patterned over the first stack of nanoribbons, and the dummy gate material is removed from the first side of the dielectric wall. The mask opening may be patterned with an edge-placement error (EPE) or more to the dielectric wall, e.g., to ensure the mask opening is always over the correct tub.

In some embodiments, opening the cavity on a first side of the dielectric wall (e.g., between the dielectric wall and a first dielectric spine) exposes the first stack of nanoribbons and a third stack of nanoribbons under the first stack of nanoribbons and on the same dielectric spine. The first and third stacks of nanoribbons may be processed together (e.g., to receive a same gate stack) or separately.

FIG. 4C shows mask layers 451, 452 over dummy gate 426, walls 140, spines 130, stacks 121, and tubs 401, and first cavity 450A under and through layers 451, 452, in workpiece or device 100, in accordance with some embodiments, for example, following a performance of opening operation 304. A material (e.g., metal) of dummy gate 426 has been removed from gate tub 401A, and nanoribbon stack 121A is in cavity 450A in gate tub 401A. Interface layers 422 on nanoribbons 120 of stack 121A are exposed. Sidewalls 141, 132 of wall 140 and spine 130 are exposed. Large arrows indicate the large allowable EPE (e.g., margin) that would still prevent a mistaken opening of cavity 450A in one of tubs 401D or 401B.

Returning to FIG. 3, methods 300 continue at operation 305 by removing the interface layer from the nanoribbons in the first nanoribbon stack. The interface layer may be removed by any suitable means. In many embodiments, the interface layer is removed by an etch of hydrofluoric acid (e.g., dilute hydrofluoric acid, DHF), for example, following an ozone treatment.

Returning to FIG. 3, methods 300 continue at operation 306 with forming a first dielectric stack on the nanoribbons in the first nanoribbon stack. The first dielectric stack may be formed by any suitable means. In many embodiments, a dielectric layer is grown on the nanoribbons in the first nanoribbon stack. In many embodiments, an insulator layer is deposited on the dielectric layer grown on the nanoribbons in the first nanoribbon stack. In some embodiments, a dipole dopant is deposited on the dielectric layer on the first nanoribbons or on the deposited insulator layer on the grown dielectric layer.

In some embodiments, a dielectric stack is formed on the third stack of nanoribbons concurrently with forming the first dielectric stack on the nanoribbons in the first nanoribbon stack (e.g., in the same cavity and gate tub). In some embodiments, some or all of a dielectric (or metal) stack formed on the third stack of nanoribbons is performed after or before forming the first dielectric (or metal) stack on the nanoribbons in the first nanoribbon stack. For example, a carbon (or other), first mask material may be deposited in a gate tub up to and above the top of a lower nanoribbon stack. A metal (e.g., metal nitride) or other second mask material may then be deposited over the first mask material (for example, with advantageously non-nucleated, e.g., spotty, growth) and conformally (or semi-conformally) over the upper nanoribbon stack. The (e.g., carbon) first mask material may be removed (e.g., ashed away), and the (metal nitride) second mask material deposited over a lateral surface of the first mask material may be removed with the carbon first mask material, exposing the lower nanoribbon stack, but leaving the upper nanoribbon stack covered by the conformal (or semi-conformal) second mask material.

Complementary transistors can be organized to minimize processing by performing concurrently a same gate-forming operation on both upper and lower (complementary) nanoribbon stacks. For example, an operation that shifts threshold voltages V_{T} in a certain direction (e.g., in an n-or p-direction) may be performed concurrently on n-or p-type nanoribbon stacks to the magnitudes of complementary threshold voltages V_{T} in opposite directions. Complementary nanoribbon stacks with similar magnitudes (e.g., to have either a low leakage current or a fast switching speed) may not be vertically aligned (e.g., in a same processing tub), but may be wired together to optimize the desired parameter (e.g., low leakage current or fast switching speed).

The dielectric layer grown on the first nanoribbon stack may be similar to the interface layer, e.g., a native oxide or passivation layer grown from the nanoribbons. The dielectric layer may be formed by any suitable means and of any suitable materials. The dielectric layer on the first nanoribbon stack may be much as described of layer 122A at FIG. 1A, for example, having silicon and oxygen and a thickness T₁. Although the dielectric layer may be similar to the interface layer (e.g., grown at operation 301), the dielectric layer may be grown in a more controlled fashion, for example, to a precise and controlled thickness. In some embodiments, the dielectric layer is grown from the nanoribbons, and a portion of a thickness of the dielectric layer is consumed from a thickness of the nanoribbon. A thicker dielectric layer may correspond with a further-thinned nanoribbon. In many embodiments, the dielectric layer is grown on the first nanoribbon stack using an ozone treatment.

An insulator layer may be deposited on the grown dielectric layer on the first nanoribbons. In many embodiments, the deposited insulator layer is a high-k dielectric layer. The deposited insulator layer may be much as described of layer 123A at FIG. 1A, for example, having oxygen and hafnium and/or zirconium and a thickness T₃. The deposited insulator layer may be formed by any suitable means and of any suitable materials. In many embodiments, the insulator layer is deposited on the grown dielectric layer on the first nanoribbons by an atomic layer deposition (ALD), which may conformally deposit the insulator layer in the gate tub (and beyond, over the entire substrate). In many embodiments, the insulator layer is deposited on the first side (e.g., first sidewall) of the dielectric wall. In many embodiments, the insulator layer is deposited on an opposing side (e.g., opposing sidewall) of the dielectric spine. An ALD (or another suitable depositing means) may deposit the insulator layer in an extremely controlled fashion and to a precise and controlled thickness.

A dipole dopant may be deposited on the dielectric layer grown on the first nanoribbons or on the deposited insulator layer on the grown dielectric layer. In some embodiments, an anneal (e.g., at an elevated temperature) is performed, for example, to drive the dipole dopant into either the grown dielectric layer or the deposited insulator layer on the grown dielectric layer. The dipole dopant may be in the grown dielectric layer (e.g., at some depth, inclusive, between the first interface between the nanoribbons and the grown dielectric layer and a second interface between the grown dielectric layer and the deposited insulator layer) or in or on the deposited insulator layer (e.g., at some depth, inclusive, between the second interface between the grown dielectric layer and the deposited insulator layer and an outer surface of the deposited insulator layer). The anneal (e.g., to drive the dipole dopant into either of the layers) may be performed at any suitable point during methods 300, for example, before or after insulator layers are deposited on nanoribbons in the second nanoribbon stack. A separate anneal (e.g., done on only the insulator layers on nanoribbons in the first nanoribbon stack) may drive the dipole dopant to a different depth in the first nanoribbons than in the second nanoribbons.

FIG. 4D illustrates dielectric layer 122A on nanoribbons 120 in first stack 121A, first cavity 450A, and first gate tub 401A, in workpiece or device 100, in accordance with some embodiments, for example, following a performance of removing and forming operations 305 and 306. Notably, dielectric layer 122A is on nanoribbons 120 in first nanoribbon stack 121A, but not on sidewalls 141, 132 of first cavity 450A and tub 401A.

FIG. 4E shows insulator layer 123A on dielectric layer 122A on nanoribbons 120 in first stack 121A, first cavity 450A, and first gate tub 401A in workpiece or device 100, in accordance with some embodiments, for example, following a performance of forming operation 306. Notably, insulator layer 123A is over layer 122A and nanoribbons 120 in nanoribbon stack 121A, as well as conformally on sidewalls 141, 132 of first cavity 450A and tub 401A and mask layer 452.

Returning to FIG. 3, methods 300 continue by depositing a first metal layer on the first dielectric stack at operation 307. The first metal layer may be a capping layer that protects the dielectric stack, for example, from further processing. In many embodiments, the first metal layer is a WFM layer. The first metal layer may be much as described of layer 127 in first gate stack 125A at FIG. 1A, for example, having a thickness T₅. The first metal layer may be formed by any suitable means and of any suitable materials, including non-metallic materials. In many embodiments, the first metal layer includes nitrogen (e.g., in a metal nitride). In some embodiments, the first metal layer includes titanium and nitrogen (e.g., in a nitride of titanium). In many embodiments, the first metal layer is deposited by a CVD (chemical vapor deposition) or ALD.

The cavity or gate tub may be filled with a sacrificial material, e.g., to cover the deposited gate stack layers during further processing. The sacrificial material may help retain the deposited layers adjacent the nanoribbons while allowing removal of the layers elsewhere, such as on a hardmask layer over the gate tubs. In some embodiments, the sacrificial material includes carbon (e.g., in a carbon hardmask). In some embodiments, the sacrificial material is cured with a nitrogen treatment. In some embodiments, the deposited layers on a hardmask layer over the gate tubs are removed by one or more isotropic etches and/or a CMP (chemical-mechanical planarization or polish).

FIG. 4F illustrates first metal layer 127 on insulator layer 123A on dielectric layer 122A on nanoribbons 120 in first stack 121A, first cavity 450A, and first gate tub 401A in workpiece or device 100, in accordance with some embodiments, for example, following a performance of depositing operation 307. Notably, metal layer 127 is on insulator layer 123A in nanoribbon stack 121A, as well as conformally on insulator layer 123A over sidewall 141 (and other sidewalls of first cavity 450A and tub 401A) and mask layer 452.

Returning to FIG. 3, methods 300 continue with opening a second cavity on a second side of the dielectric wall at operation 308. The performance of operation 308 may be similar to the performance of operation 304, e.g., except on an opposing side of the dielectric wall. The second cavity may be a gate tub for processing the second stack of nanoribbons. The second cavity may be opened by any suitable means. In many embodiments, the second cavity is opened by removing the second portion of the dummy gate from the second sidewall and from over the second stack of nanoribbons. In many embodiments, the dummy gate material is removed by a selective isotropic etch. In some embodiments, the dummy gate material is removed by a wet etch. In some embodiments, a mask layer is deposited over the substrate, a mask opening is patterned over the second stack of nanoribbons, and the dummy gate material is removed from the second side of the dielectric wall. The deposited mask layer may be a second mask layer following a removal (for example, by a CMP) of a first mask layer (e.g., at operation 304, etc.).

In some embodiments, opening the second cavity on a second side of the dielectric wall (e.g., between the dielectric wall and a second dielectric spine) exposes the second stack of nanoribbons and a fourth stack of nanoribbons under the second stack of nanoribbons and on the same dielectric spine. The second and fourth stacks of nanoribbons may be processed together (e.g., to receive a same gate stack) or separately.

FIG. 4G shows mask layers 451, 452 over dummy gate 426, walls 140, stacks 121A, 121B, and tubs 401A, 401B, and second cavity 450B under and through layers 451, 452, in workpiece or device 100, in accordance with some embodiments, for example, following a performance of opening operation 308. A material (e.g., metal) of dummy gate 426 has been removed from gate tub 401B, and nanoribbon stack 121B is in cavity 450B in gate tub 401B. Interface layers 422 on nanoribbons 120 of stack 121B are exposed. Sidewalls 142, 131 of wall 140 and spine 130 are exposed. A sacrificial material 446 is on layer 127 in first gate tub 401A. Upper horizontal portions of conformal layers 123A, 127 over electrode 126 may have been removed, e.g., by a CMP that also removed one or more mask layers 452, etc., over substrate 199.

Returning to FIG. 3, methods 300 continue at operation 309 by removing the interface layer from the nanoribbons in the second nanoribbon stack. The performance of operation 309 may be similar to the performance of operation 305, e.g., except on the second nanoribbon stack. The interface layer may be removed by any suitable means. In many embodiments, the interface layer is removed by a hydrofluoric acid etch.

Returning to FIG. 3, methods 300 continue at operation 310 with forming a second dielectric stack on the nanoribbons in the second nanoribbon stack. The performance of operation 310 may be similar to the performance of operation 306, e.g., except on the second nanoribbon stack. Significantly, the performance of operation 310 on the second nanoribbon stack may be done with different materials, to different dimensions, etc., and the second dielectric stack may have different characteristics than the first dielectric stack. The second dielectric stack may be formed by any suitable means. In many embodiments, a dielectric layer is grown on the nanoribbons in the second nanoribbon stack. In many embodiments, an insulator layer is deposited on the dielectric layer grown on the nanoribbons in the second nanoribbon stack. In some embodiments, a dipole dopant is deposited on the dielectric layer on the second nanoribbons or on the deposited insulator layer on the grown dielectric layer.

The dielectric layer may be formed on the second nanoribbons by any suitable means and of any suitable materials. The dielectric layer on the second nanoribbon stack may be much as described of layer 122B at FIG. 1A, for example, having silicon and oxygen and a thickness T₂. Notably, the dielectric layer formed on the second nanoribbons may have a different thickness or material composition than the dielectric layer formed on the first nanoribbons.

An insulator layer may be deposited on the grown dielectric layer on the second nanoribbons. In many embodiments, the deposited insulator layer is a high-k dielectric layer. In many embodiments, the deposited insulator layer is deposited on exposed sidewalls of the gate tub, on opposing sidewalls of the dielectric wall and spine. The deposited insulator layer may be much as described of layer 123B at FIG. 1A, for example, having oxygen and hafnium and/or zirconium and a thickness T₄. The deposited insulator layer may be formed by any suitable means and of any suitable materials. Notably, the deposited insulator layer formed over the second nanoribbons may have a different thickness or material composition than the deposited insulator layer formed over the first nanoribbons.

A dipole dopant may be deposited on the dielectric layer grown on the second nanoribbons or on the deposited insulator layer over the second nanoribbons. Notably, the dipole dopant deposited over the second nanoribbons may be of the same or a different material than the dopant deposited over the first nanoribbons and may be deposited at a different concentration or thickness, or driven to a different depth in the corresponding dielectric stack than the dopant deposited over the first nanoribbons.

FIG. 4H illustrates dielectric layer 122B on nanoribbons 120 in second stack 121B, second cavity 450B, and second gate tub 401B, in workpiece or device 100, in accordance with some embodiments, for example, following a performance of removing and forming operations 309 and 310. Notably, dielectric layer 122B is on nanoribbons 120 in second nanoribbon stack 121B, but not on sidewalls 142, 131 of second cavity 450B and tub 401B.

FIG. 4I shows insulator layer 123B on dielectric layer 122B on nanoribbons 120 in second stack 121B, second cavity 450B, and second gate tub 401B in workpiece or device 100, in accordance with some embodiments, for example, following a performance of forming operation 310. Notably, insulator layer 123B is over layer 122B and nanoribbons 120 in nanoribbon stack 121B, as well as conformally on sidewalls 142, 131 of second cavity 450B and tub 401B and mask layer 452.

Returning to FIG. 3, methods 300 continue by depositing a second metal layer on the second dielectric stack at operation 311. The performance of operation 311 may be similar to the performance of operation 307, e.g., except on the second dielectric stack. Significantly, the performance of operation 311 on the second dielectric stack may be done with different materials, to different dimensions, etc., and the second gate stack may have different characteristics than the first gate stack. The second metal layer may be a capping layer that protects the second dielectric stack, for example, from further processing. In many embodiments, the second metal layer is a WFM layer. The second metal layer may be much as described of layer 127 in second gate stack 125B at FIG. 1A, for example, having a thickness T₆. The second metal layer may be formed by any suitable means and of any suitable materials, including non-metallic materials. In many embodiments, the second metal layer includes nitrogen. In some embodiments, the second metal layer includes titanium and nitrogen.

Processing of third, fourth, etc., gate stacks on third, fourth, etc., nanoribbon stacks may be done similarly to the processing of the first and second gate stacks and nanoribbons, e.g., concurrently, completely independently, or some mixture of shared and separate operations.

FIG. 4J illustrates second metal layer 127 on insulator layer 123B on dielectric layer 122B on nanoribbons 120 in second stack 121B, second cavity 450B, and second gate tub 401B in workpiece or device 100, in accordance with some embodiments, for example, following a performance of depositing operation 311. Notably, metal layer 127 is on insulator layer 123B in nanoribbon stack 121B, as well as conformally on insulator layer 123B over sidewalls 142, 131 of second cavity 450B and tub 401B and mask layer 452.

Returning to FIG. 3, methods 300 continue at operation 312 by forming a first gate electrode over the first nanoribbon stack and a second gate electrode over the second nanoribbon stack. The dielectric wall may be retained, and the first and second gate electrodes may be separated by the dielectric wall. The first and second gate electrodes may be formed by any suitable means and of any suitable materials, including non-metallic materials. The first and second gate electrodes may be much as described of electrodes 126 in transistor structures 101A, 101B at FIG. 1A (for example, having layers 127, 128). The first and second gate electrodes may be formed of the same or different materials, e.g., having the same or different layers 127, 128.

FIG. 4K shows sacrificial material 446 on layers 127 in first and second gate tubs 401A, 401B in workpiece or device 100, in accordance with some embodiments, for example, during or prior to a performance of forming operation 312. Mask layers are not present over dummy gate 426, walls 140, spines 130, stacks 121, and tubs 401.

FIG. 4L illustrates IC device 100 with transistor structures 101A, 101B, 101C, 101D having different gate stacks 125A, 125B, 125C, 125D in adjacent gate electrodes 126 separated by a slim dielectric wall 140, in accordance with some embodiments, for example, following a performance of forming operation 312. Gate vias 129 through dielectric layer 149 couple gate electrodes 126 and transistor structures 101A, 101B, 101C, 101D, for example, with an interconnect network (not shown) above structures 101.

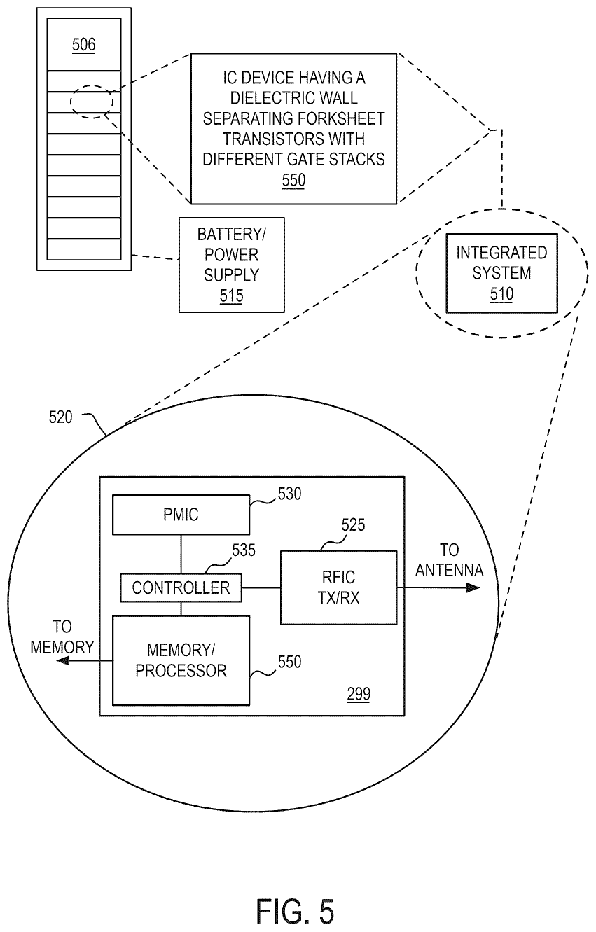

FIG. 5 illustrates a diagram of an example data server machine 506 employing an IC device having dielectric walls separating forksheet transistors with different gate stacks, in accordance with some embodiments. Server machine 506 may be any commercial server, for example, including any number of high-performance computing platforms disposed within a rack and networked together for electronic data processing, which in the exemplary embodiment includes one or more devices 550 having dielectric walls separating forksheet transistors with different gate stacks.

Also as shown, server machine 506 includes a battery and/or power supply 515 to provide power to devices 550, and to provide, in some embodiments, power delivery functions such as power regulation. Devices 550 may be deployed as part of a package-level integrated system 510. Integrated system 510 is further illustrated in the expanded view 520. In the exemplary embodiment, devices 550 (labeled “Memory/Processor”) includes at least one memory chip (e.g., random-access memory (RAM)), and/or at least one processor chip (e.g., a microprocessor, a multi-core microprocessor, or graphics processor, or the like) having the characteristics discussed herein. In an embodiment, device 550 is a microprocessor including a static RAM (SRAM) cache memory. As shown, device 550 may be an IC device having dielectric walls separating forksheet transistors with different gate stacks, as discussed herein. Device 550 may be further coupled to (e.g., communicatively coupled to) a board, an interposer, or other substrate or host component 299 along with, one or more of a power management IC (PMIC) 530, RF (wireless) IC (RFIC) 525 including a wideband RF (wireless) transmitter and/or receiver (TX/RX) (e.g., including a digital baseband and an analog front-end module further includes a power amplifier on a transmit path and a low noise amplifier on a receive path), and a controller 535 thereof. In some embodiments, RFIC 525, PMIC 530, controller 535, and device 550 include having dielectric walls separating forksheet transistors with different gate stacks.

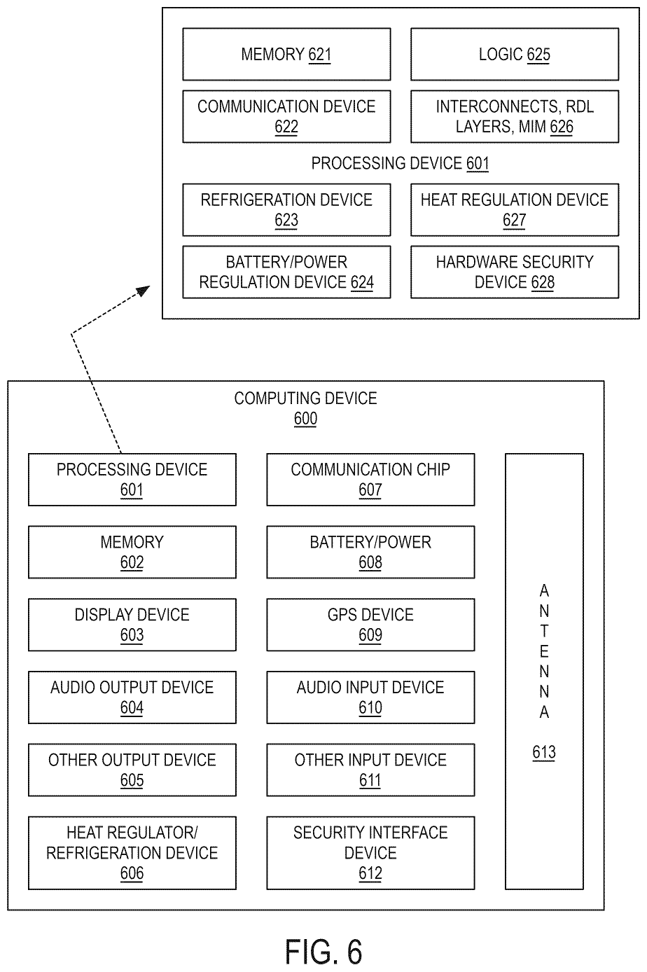

FIG. 6 is a block diagram of an example computing device 600, in accordance with some embodiments. For example, one or more components of computing device 600 may include any of the devices or structures discussed herein. A number of components are illustrated in FIG. 6 as being included in computing device 600, but any one or more of these components may be omitted or duplicated, as suitable for the application. In some embodiments, some or all of the components included in computing device 600 may be attached to one or more printed circuit boards (e.g., a motherboard). In some embodiments, various ones of these components may be fabricated onto a single system-on-a-chip (SoC) die. Additionally, in various embodiments, computing device 600 may not include one or more of the components illustrated in FIG. 6, but computing device 600 may include interface circuitry for coupling to the one or more components. For example, computing device 600 may not include a display device 603, but may include display device interface circuitry (e.g., a connector and driver circuitry) to which display device 603 may be coupled. In another set of examples, computing device 600 may not include an audio output device 604, other output device 605, global positioning system (GPS) device 609, audio input device 610, or other input device 611, but may include audio output device interface circuitry, other output device interface circuitry, GPS device interface circuitry, audio input device interface circuitry, audio input device interface circuitry, to which audio output device 604, other output device 605, GPS device 609, audio input device 610, or other input device 611 may be coupled.

Computing device 600 may include a processing device 601 (e.g., one or more processing devices). As used herein, the term “processing device” or “processor” indicates a device that processes electronic data from registers and/or memory to transform that electronic data into other electronic data that may be stored in registers and/or memory. Processing device 601 may include a memory 621, a communication device 622, a refrigeration device 623, a battery/power regulation device 624, logic 625, interconnects 626 (i.e., optionally including redistribution layers (RDL) or metal-insulator-metal (MIM) devices), a heat regulation device 627, and a hardware security device 628.

Processing device 601 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 600 may include a memory 602, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 602 includes memory that shares a die with processing device 601. This memory may be used as cache memory and may include embedded dynamic random-access memory (eDRAM) or spin transfer torque magnetic random-access memory (STT-MRAM).

Computing device 600 may include a heat regulation/refrigeration device 606. Heat regulation/refrigeration device 606 may maintain processing device 601 (and/or other components of computing device 600) at a predetermined low temperature during operation.

In some embodiments, computing device 600 may include a communication chip 607 (e.g., one or more communication chips). For example, the communication chip 607 may be configured for managing wireless communications for the transfer of data to and from computing device 600. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 607 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 607 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 607 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 607 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 607 may operate in accordance with other wireless protocols in other embodiments. Computing device 600 may include an antenna 613 to facilitate wireless communications and/or to receive other wireless communications (such as AM or FM radio transmissions).

In some embodiments, communication chip 607 may manage wired communications, such as electrical, optical, or any other suitable communication protocols (e.g., the Ethernet). As noted above, communication chip 607 may include multiple communication chips. For instance, a first communication chip 607 may be dedicated to shorter-range wireless communications such as Wi-Fi or Bluetooth, and a second communication chip 607 may be dedicated to longer-range wireless communications such as GPS, EDGE, GPRS, CDMA, WiMAX, LTE, EV-DO, or others. In some embodiments, a first communication chip 607 may be dedicated to wireless communications, and a second communication chip 607 may be dedicated to wired communications.

Computing device 600 may include battery/power circuitry 608. Battery/power circuitry 608 may include one or more energy storage devices (e.g., batteries or capacitors) and/or circuitry for coupling components of computing device 600 to an energy source separate from computing device 600 (e.g., AC line power).

Computing device 600 may include a display device 603 (or corresponding interface circuitry, as discussed above). Display device 603 may include any visual indicators, such as a heads-up display, a computer monitor, a projector, a touchscreen display, a liquid crystal display (LCD), a light-emitting diode display, or a flat panel display, for example.

Computing device 600 may include an audio output device 604 (or corresponding interface circuitry, as discussed above). Audio output device 604 may include any device that generates an audible indicator, such as speakers, headsets, or earbuds, for example.

Computing device 600 may include an audio input device 610 (or corresponding interface circuitry, as discussed above). Audio input device 610 may include any device that generates a signal representative of a sound, such as microphones, microphone arrays, or digital instruments (e.g., instruments having a musical instrument digital interface (MIDI) output).

Computing device 600 may include a GPS device 609 (or corresponding interface circuitry, as discussed above). GPS device 609 may be in communication with a satellite-based system and may receive a location of computing device 600, as known in the art.

Computing device 600 may include other output device 605 (or corresponding interface circuitry, as discussed above). Examples of the other output device 605 may include an audio codec, a video codec, a printer, a wired or wireless transmitter for providing information to other devices, or an additional storage device.

Computing device 600 may include other input device 611 (or corresponding interface circuitry, as discussed above). Examples of the other input device 611 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 600 may include a security interface device 612. Security interface device 612 may include any device that provides security measures for computing device 600 such as intrusion detection, biometric validation, security encode or decode, access list management, malware detection, or spyware detection.

Computing device 600, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1A-6. The subject matter may be applied to other deposition applications, as well as any appropriate manufacturing application, as will be understood to those skilled in the art.

The following examples pertain to further embodiments, and specifics in the examples may be used anywhere in one or more embodiments.

In one or more first embodiments, an apparatus includes first, second, and third dielectric walls in an IC substrate, the third dielectric wall between the first and second dielectric walls, a first stack of first nanoribbons on the first dielectric wall and through a first gate structure in a first transistor structure, the first gate structure including a first dielectric layer on the first and third dielectric walls and between a pair of the first nanoribbons, and a second stack of second nanoribbons on the second dielectric wall and through a second gate structure in a second transistor structure, the second gate structure including a second dielectric layer on the second and third dielectric walls and between a pair of the second nanoribbons.

In one or more second embodiments, further to the first embodiments, the apparatus also includes fourth and fifth dielectric walls in the IC substrate, the first dielectric wall between the third and fourth dielectric walls, the second dielectric wall between the third and fifth dielectric walls, a third stack of third nanoribbons on the first dielectric wall and through a third gate structure in a third transistor structure, the third gate structure including a third dielectric layer on the first and fourth dielectric walls and between a pair of the third nanoribbons, and a fourth stack of fourth nanoribbons on the second dielectric wall and through a fourth gate structure in a fourth transistor structure, the fourth gate structure including a fourth dielectric layer on the second and fifth dielectric walls and between a pair of the fourth nanoribbons, wherein a composition of the third dielectric layer is different than compositions of the first, second, and fourth dielectric layers, and the composition of fourth dielectric layer is different than the compositions of the first and second dielectric layers.

In one or more third embodiments, further to the first or second embodiments, the apparatus also includes a third stack of third nanoribbons under the first stack of first nanoribbons, on the first dielectric wall, and in a third transistor structure, and a fourth stack of fourth nanoribbons under the second stack of second nanoribbons, on the second dielectric wall, and in a fourth transistor structure, the third and fourth stacks of third and fourth nanoribbons between the first and second dielectric walls, wherein the first and second transistor structures are of a first conductivity type, and the third and fourth transistor structures are of a second conductivity type.

In one or more fourth embodiments, further to the first through third embodiments, the third stack of third nanoribbons are through a third gate structure in the third transistor structure, and an insulator layer is between the first and third gate structures.

In one or more fifth embodiments, further to the first through fourth embodiments, the first gate structure includes a first metal between the first and third dielectric walls and between the pair of the first nanoribbons, the first dielectric layer between the first metal and the first dielectric wall, the first metal and the third dielectric wall, the first metal and an upper one of the pair of the first nanoribbons, and the first metal and a lower one of the pair of the first nanoribbons, and the second gate structure includes a second metal between the second and third dielectric walls and between the pair of the second nanoribbons, the second dielectric layer between the second metal and the second dielectric wall, the second metal and the third dielectric wall, the second metal and an upper one of the pair of the second nanoribbons, and the second metal and a lower one of the pair of the second nanoribbons.

In one or more sixth embodiments, further to the first through fifth embodiments, a first width of the third dielectric wall is less than a second width of the first dielectric wall.

In one or more seventh embodiments, further to the first through sixth embodiments, a width of the third dielectric wall is less than 12 nm, and a distance between the first stack of first nanoribbons and the second stack of second nanoribbons is less than 36 nm.

In one or more eighth embodiments, further to the first through seventh embodiments, a width of the third dielectric wall is approximately equal to a distance between the third dielectric wall and the first stack of first nanoribbons.

In one or more ninth embodiments, further to the first through eighth embodiments, the first dielectric layer has a first thickness and a first composition, the second dielectric layer has a second thickness and a second composition, and the second thickness is greater than the first thickness or the second composition is different than the first composition.

In one or more tenth embodiments, further to the first through ninth embodiments, the IC substrate is coupled to a host component, and the IC substrate is coupled to a power supply through the host component.

In one or more eleventh embodiments, an apparatus includes a dielectric spine between and in contact with a first stack of first nanoribbons and a second stack of second nanoribbons, a first gate structure between the dielectric spine and a first dielectric wall, the first stack of first nanoribbons through the first gate structure in a first transistor structure, the first gate structure including a first dielectric layer on the dielectric spine and the first dielectric wall and between a pair of the first nanoribbons, and a second gate structure between the dielectric spine and a second dielectric wall, the second stack of second nanoribbons through the second gate structure in a second transistor structure, the second gate structure including a second dielectric layer on the dielectric spine and the second dielectric wall and between a pair of the second nanoribbons.

In one or more twelfth embodiments, further to the eleventh embodiments, the apparatus also includes a third stack of third nanoribbons under the first stack of first nanoribbons, on the dielectric spine, and in a third transistor structure, and a fourth stack of fourth nanoribbons under the second stack of second nanoribbons, on the dielectric spine, and in a fourth transistor structure, wherein the first and second transistor structures are of a first conductivity type, and the third and fourth transistor structures are of a second conductivity type.

In one or more thirteenth embodiments, further to the eleventh or twelfth embodiments, the dielectric spine is a first dielectric spine, and the apparatus also includes a second dielectric spine between and in contact with a third stack of third nanoribbons and a fourth stack of fourth nanoribbons, a third gate structure between the second dielectric spine and the second dielectric wall, the third stack of third nanoribbons through the third gate structure in a third transistor structure, the third gate structure including a third dielectric layer on the second dielectric spine and the second dielectric wall and between a pair of the third nanoribbons, and a fourth gate structure between the second dielectric spine and a third dielectric wall, the fourth stack of fourth nanoribbons through the fourth gate structure in a fourth transistor structure, the fourth gate structure including a fourth dielectric layer on the second dielectric spine and the third dielectric wall and between a pair of the fourth nanoribbons, wherein a composition of the third dielectric layer is different than compositions of the first, second, and fourth dielectric layers, and the composition of the fourth dielectric layer is different than the compositions of the first and second dielectric layers.

In one or more fourteenth embodiments, further to the eleventh through thirteenth embodiments, the apparatus is coupled to a host component, and the apparatus is coupled to a power supply through the host component.

In one or more fifteenth embodiments, a method includes forming a first dielectric wall between a first stack of first nanoribbons and a second stack of second nanoribbons, the first stack of first nanoribbons on a second dielectric wall, the second stack of second nanoribbons on a third dielectric wall, the first and second stacks of first and second nanoribbons between the second and third dielectric walls, the first dielectric wall between the first and second stacks of first and second nanoribbons, opening a cavity between the first and second dielectric walls, forming a dielectric stack on the first nanoribbons, and forming a gate electrode over the first stack of first nanoribbons.

In one or more sixteenth embodiments, further to the fifteenth embodiments, the forming the first dielectric wall forms separate first and second tubs, the first stack of first nanoribbons in the first tub and the second stack of second nanoribbons in the second tub, both the first and second tubs not including a third stack of nanoribbons, the cavity between the first and second dielectric walls is a first cavity in the first tub, the dielectric stack on the first nanoribbons is a first dielectric stack, and the gate electrode over the first stack of first nanoribbons is a first gate electrode, and the method also includes opening a second cavity in the second tub between the first and third dielectric walls, forming a second dielectric stack on the second nanoribbons, and forming a second gate electrode over the second stack of second nanoribbons, the first dielectric wall between the first and second gate electrodes.

In one or more seventeenth embodiments, further to the fifteenth or sixteenth embodiments, the forming the first and second dielectric stacks forms the first and second dielectric stacks with different compositions or thicknesses.

In one or more eighteenth embodiments, further to the fifteenth through seventeenth embodiments, the forming the dielectric stack on the first nanoribbons deposits a dielectric layer on a sidewall of the first dielectric wall.

In one or more nineteenth embodiments, further to the fifteenth through eighteenth embodiments, the method also includes forming a dummy gate between the second and third dielectric walls by depositing a metal over and between the first nanoribbons in the first stack and over and between the second nanoribbons in the second stack, wherein the forming the first dielectric wall between the first stack of first nanoribbons and the second stack of second nanoribbons forms the first dielectric wall through the dummy gate.

In one or more twentieth embodiments, further to the fifteenth through nineteenth embodiments, the forming the first dielectric wall between the first stack of first nanoribbons and the second stack of second nanoribbons forms the first dielectric wall between a third stack of third nanoribbons and a fourth stack of fourth nanoribbons, the third stack of third nanoribbons under the first stack of first nanoribbons on the second dielectric wall, the fourth stack of fourth nanoribbons under the second stack of second nanoribbons on the third dielectric wall, the first stack of first nanoribbons coupled between first and second semiconductor bodies of a first conductivity type, the third stack of third nanoribbons coupled between third and fourth semiconductor bodies of a second conductivity type, and the opening the cavity between the first and second dielectric walls exposes the first stack of first nanoribbons and the third stack of third nanoribbons.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. An apparatus, comprising:
first, second, and third dielectric walls in an integrated circuit (IC) substrate, the third dielectric wall between the first and second dielectric walls;
a first stack of first nanoribbons on the first dielectric wall and through a first gate structure in a first transistor structure, the first gate structure comprising a first dielectric layer on the first and third dielectric walls and between a pair of the first nanoribbons; and
a second stack of second nanoribbons on the second dielectric wall and through a second gate structure in a second transistor structure, the second gate structure comprising a second dielectric layer on the second and third dielectric walls and between a pair of the second nanoribbons.

2. The apparatus of claim 1, further comprising:
fourth and fifth dielectric walls in the IC substrate, the first dielectric wall between the third and fourth dielectric walls, the second dielectric wall between the third and fifth dielectric walls;
a third stack of third nanoribbons on the first dielectric wall and through a third gate structure in a third transistor structure, the third gate structure comprising a third dielectric layer on the first and fourth dielectric walls and between a pair of the third nanoribbons; and
a fourth stack of fourth nanoribbons on the second dielectric wall and through a fourth gate structure in a fourth transistor structure, the fourth gate structure comprising a fourth dielectric layer on the second and fifth dielectric walls and between a pair of the fourth nanoribbons, wherein a composition of the third dielectric layer is different than compositions of the first, second, and fourth dielectric layers, and the composition of fourth dielectric layer is different than the compositions of the first and second dielectric layers.

3. The apparatus of claim 1, further comprising:
a third stack of third nanoribbons under the first stack of first nanoribbons, on the first dielectric wall, and in a third transistor structure; and
a fourth stack of fourth nanoribbons under the second stack of second nanoribbons, on the second dielectric wall, and in a fourth transistor structure, the third and fourth stacks of third and fourth nanoribbons between the first and second dielectric walls, wherein the first and second transistor structures are of a first conductivity type, and the third and fourth transistor structures are of a second conductivity type.

4. The apparatus of claim 3, wherein the third stack of third nanoribbons are through a third gate structure in the third transistor structure, and an insulator layer is between the first and third gate structures.

5. The apparatus of claim 1, wherein:
the first gate structure comprises a first metal between the first and third dielectric walls and between the pair of the first nanoribbons, the first dielectric layer between:
the first metal and the first dielectric wall;
the first metal and the third dielectric wall;
the first metal and an upper one of the pair of the first nanoribbons; and
the first metal and a lower one of the pair of the first nanoribbons; and
the second gate structure comprises a second metal between the second and third dielectric walls and between the pair of the second nanoribbons, the second dielectric layer between:
the second metal and the second dielectric wall;
the second metal and the third dielectric wall;
the second metal and an upper one of the pair of the second nanoribbons; and
the second metal and a lower one of the pair of the second nanoribbons.

6. The apparatus of claim 1, wherein a first width of the third dielectric wall is less than a second width of the first dielectric wall.

7. The apparatus of claim 1, wherein:
a width of the third dielectric wall is less than 12 nm; and
a distance between the first stack of first nanoribbons and the second stack of second nanoribbons is less than 36 nm.

8. The apparatus of claim 1, wherein a width of the third dielectric wall is approximately equal to a distance between the third dielectric wall and the first stack of first nanoribbons.

9. The apparatus of claim 1, wherein:
the first dielectric layer has a first thickness and a first composition;
the second dielectric layer has a second thickness and a second composition; and
the second thickness is greater than the first thickness or the second composition is different than the first composition.

10. The apparatus of claim 1, wherein the IC substrate is coupled to a host component, and the IC substrate is coupled to a power supply through the host component.

11. An apparatus, comprising:
a dielectric spine between and in contact with a first stack of first nanoribbons and a second stack of second nanoribbons;
a first gate structure between the dielectric spine and a first dielectric wall, the first stack of first nanoribbons through the first gate structure in a first transistor structure, the first gate structure comprising a first dielectric layer on the dielectric spine and the first dielectric wall and between a pair of the first nanoribbons; and
a second gate structure between the dielectric spine and a second dielectric wall, the second stack of second nanoribbons through the second gate structure in a second transistor structure, the second gate structure comprising a second dielectric layer on the dielectric spine and the second dielectric wall and between a pair of the second nanoribbons.

12. The apparatus of claim 11, further comprising:
a third stack of third nanoribbons under the first stack of first nanoribbons, on the dielectric spine, and in a third transistor structure; and
a fourth stack of fourth nanoribbons under the second stack of second nanoribbons, on the dielectric spine, and in a fourth transistor structure, wherein the first and second transistor structures are of a first conductivity type, and the third and fourth transistor structures are of a second conductivity type.

13. The apparatus of claim 11, wherein the dielectric spine is a first dielectric spine, and further comprising:
a second dielectric spine between and in contact with a third stack of third nanoribbons and a fourth stack of fourth nanoribbons;
a third gate structure between the second dielectric spine and the second dielectric wall, the third stack of third nanoribbons through the third gate structure in a third transistor structure, the third gate structure comprising a third dielectric layer on the second dielectric spine and the second dielectric wall and between a pair of the third nanoribbons; and
a fourth gate structure between the second dielectric spine and a third dielectric wall, the fourth stack of fourth nanoribbons through the fourth gate structure in a fourth transistor structure, the fourth gate structure comprising a fourth dielectric layer on the second dielectric spine and the third dielectric wall and between a pair of the fourth nanoribbons, wherein a composition of the third dielectric layer is different than compositions of the first, second, and fourth dielectric layers, and the composition of the fourth dielectric layer is different than the compositions of the first and second dielectric layers.

14. The apparatus of claim 13, wherein the apparatus is coupled to a host component, and the apparatus is coupled to a power supply through the host component.

15. A method, comprising:
forming a first dielectric wall between a first stack of first nanoribbons and a second stack of second nanoribbons, the first stack of first nanoribbons on a second dielectric wall, the second stack of second nanoribbons on a third dielectric wall, the first and second stacks of first and second nanoribbons between the second and third dielectric walls, the first dielectric wall between the first and second stacks of first and second nanoribbons;
opening a cavity between the first and second dielectric walls;
forming a dielectric stack on the first nanoribbons; and
forming a gate electrode over the first stack of first nanoribbons.

16. The method of claim 15, wherein:
the forming the first dielectric wall forms separate first and second tubs, the first stack of first nanoribbons in the first tub and the second stack of second nanoribbons in the second tub, both the first and second tubs not comprising a third stack of nanoribbons;
the cavity between the first and second dielectric walls is a first cavity in the first tub;
the dielectric stack on the first nanoribbons is a first dielectric stack; and
the gate electrode over the first stack of first nanoribbons is a first gate electrode; and
further comprising:
opening a second cavity in the second tub between the first and third dielectric walls;
forming a second dielectric stack on the second nanoribbons; and
forming a second gate electrode over the second stack of second nanoribbons, the first dielectric wall between the first and second gate electrodes.

17. The method of claim 16, wherein the forming the first and second dielectric stacks forms the first and second dielectric stacks with different compositions or thicknesses.

18. The method of claim 15, wherein the forming the dielectric stack on the first nanoribbons deposits a dielectric layer on a sidewall of the first dielectric wall.

19. The method of claim 15, further comprising forming a dummy gate between the second and third dielectric walls by depositing a metal over and between the first nanoribbons in the first stack and over and between the second nanoribbons in the second stack, wherein the forming the first dielectric wall between the first stack of first nanoribbons and the second stack of second nanoribbons forms the first dielectric wall through the dummy gate.

20. The method of claim 15, wherein:
the forming the first dielectric wall between the first stack of first nanoribbons and the second stack of second nanoribbons forms the first dielectric wall between a third stack of third nanoribbons and a fourth stack of fourth nanoribbons, the third stack of third nanoribbons under the first stack of first nanoribbons on the second dielectric wall, the fourth stack of fourth nanoribbons under the second stack of second nanoribbons on the third dielectric wall, the first stack of first nanoribbons coupled between first and second semiconductor bodies of a first conductivity type, the third stack of third nanoribbons coupled between third and fourth semiconductor bodies of a second conductivity type; and
the opening the cavity between the first and second dielectric walls exposes the first stack of first nanoribbons and the third stack of third nanoribbons.
